(19) United States
(12) Patent Application Publication
(10) Pub. No.: US 2025/0061258 A1
(43) Pub. Date: Feb. 20, 2025

(54) METHOD AND APPARATUS FOR DETERMINING PARAMETER OF LAYOUT QUALITY DETECTION TOOL, DEVICE, AND MEDIUM

(71) Applicant: Tencent Technology (Shenzhen) Company Limited, Shenzhen (CN)

(72) Inventors: Xingyu MA, Shenzhen (CN); Shaogang HAO, Shenzhen (CN); Shengyu ZHANG, Shenzhen (CN)

(21) Appl. No.: 18/770,482

(22) Filed: Jul. 11, 2024

Related U.S. Application Data
(63) Continuation of application No. PCT/CN2023/131179, filed on Nov. 13, 2023.

(30) Foreign Application Priority Data
Aug. 14, 2023 (CN) 202311022025.7

(51) Int. Cl. G06F 30/392; G06F 30/398

(52) U.S. Cl. CPC G06F 30/392; G06F 30/398

(57) ABSTRACT

A method for determining a parameter of a layout quality detection tool performed by an electronic device. The method includes: performing a quality detection on an original chip layout by using a layout quality detection tool to obtain quality indicators corresponding to first base values; when the quality indicators do not meet a reference condition, determining a first reference value from a plurality of first candidate values based on the quality indicators, and determining a plurality of second base values based on the plurality of first base values and the first reference value; performing a quality detection on the original chip layout by using the tool to obtain quality indicators corresponding to the second base values; and when the quality indicators meet the reference condition, determining a target value of the target parameter based on the second base values for improving the accuracy of the tool.

### CROSS-REFERENCE TO RELATED APPLICATIONS

This application is a continuation application of PCT Patent Application No. PCT/CN2023/131179, entitled “METHOD AND APPARATUS FOR DETERMINING PARAMETER OF LAYOUT QUALITY DETECTION TOOL, DEVICE, AND MEDIUM” filed on Nov. 13, 2023, which claims priority to Chinese Patent Application No. 202311022025.7, entitled “METHOD AND APPARATUS FOR DETERMINING PARAMETER OF LAYOUT QUALITY DETECTION TOOL, DEVICE, AND MEDIUM” filed on Aug. 14, 2023, both of which are incorporated by reference in their entirety.

### FIELD OF THE TECHNOLOGY

Embodiments of this application relate to the field of computer technologies, and in particular, to a method and an apparatus for determining a parameter of a layout quality detection tool, a device, and a medium.

### BACKGROUND OF THE DISCLOSURE

With the development of computer technologies, integrated circuit technologies have also been developed, and an increasingly large number of layouts such as chip layouts, mask layouts, and wafer layouts have emerged. Layouts tend to have greatly varied quality, and therefore it is necessary to select a target layout from a plurality of candidate layouts.

In the related art, a plurality of candidate layouts may be inputted into a layout quality detection tool, and the layout quality detection tool determines quality indicators of the candidate layouts. If a quality indicator of one candidate layout is greater than an indicator threshold, the candidate layout is determined as a target layout. As can be learned, the accuracy of the layout quality detection tool is closely related to the accuracy of selecting the target layout, and a parameter of the layout quality detection tool determines the accuracy of the layout quality detection tool. Therefore, how to determine the parameter of the layout quality detection tool becomes a problem that needs to be resolved urgently.

### SUMMARY

This application provides a method and an apparatus for determining a parameter of a layout quality detection tool, a device, and a medium, which can determine a value of a target parameter of a layout quality detection tool, thereby improving the accuracy of the layout quality detection tool. The technical solutions include the following content.

According to an aspect, a method for determining a parameter of a layout quality detection tool is performed by an electronic device, the method including:
performing a quality detection on an original chip layout by using a layout quality detection tool according to a plurality of first base values of a target parameter of the layout quality detection tool to obtain quality indicators corresponding to the first base values;
when the quality indicators corresponding to the first base values do not meet a reference condition, determining a first reference value from a plurality of first candidate values of the target parameter of the layout quality detection tool based on the quality indicators corresponding to the first base values, and determining a plurality of second base values of the target parameter based on the plurality of first base values and the first reference value;
performing a quality detection on the original layout by using the layout quality detection tool according to the plurality of second base values to obtain quality indicators corresponding to the second base values; and
when the quality indicators corresponding to the second base values meet the reference condition, determining a target value of the target parameter based on the second base values for adjusting the layout quality detection tool to determine a quality indicator of a to-be-detected chip layout.

According to another aspect, an electronic device includes a processor and a memory, the memory having at least one computer program stored therein that, when loaded and executed by the processor, cause the electronic device to implement any foregoing method for determining a parameter of a layout quality detection tool.

According to another aspect, a non-transitory computer-readable storage medium includes at least one computer program stored therein that, when loaded and executed by a processor of an electronic device, cause the electronic device to implement any foregoing method for determining a parameter of a layout quality detection tool.

In the technical solutions provided in this application, a target parameter of a layout quality detection tool includes first base values, and a quality detection is performed on an original layout by using the layout quality detection tool to obtain quality indicators corresponding to the first base values. If the quality indicators corresponding to the first base values do not meet a reference condition, a first reference value is determined from a plurality of first candidate values of the target parameter based on the quality indicators corresponding to the first base values, and a plurality of second base values of the target parameter are determined based on the plurality of first base values and the first reference value. The second base values are determined, so that the accuracy of a value space of the target parameter is improved. A quality detection is performed on the original layout by using the layout quality detection tool to obtain quality indicators corresponding to the second base values. The accuracy of the value space of the target parameter is improved, to improve the accuracy of the layout quality detection tool, so that the accuracy of quality indicators is improved, and when the quality indicators corresponding to the second base values meet the reference condition, a target value of the target parameter can be accurately determined based on the second base values, thereby ensuring the accuracy of the layout quality detection tool, helping to improve the accuracy of quality indicators of to-be-detected layouts determined by the layout quality detection tool, and more accurately selecting a layout with better quality from the to-be-detected layouts.

### BRIEF DESCRIPTION OF THE DRAWINGS

FIG. 1 is a schematic diagram of an implementation environment of a method for determining a parameter of a layout quality detection tool according to an embodiment of this application.

FIG. 2 is a flowchart of a method for determining a parameter of a layout quality detection tool according to an embodiment of this application.

FIG. 3 is a schematic diagram of a Pareto front between a mask error and a mask complexity according to an embodiment of this application.

FIG. 4 is a schematic flowchart of determining a parameter of a layout quality detection tool for a single quality indicator according to an embodiment of this application.

FIG. 5 is a schematic flowchart of determining a parameter of a layout quality detection tool for two quality indicators according to an embodiment of this application.

FIG. 6 is a schematic diagram of a relationship between a quantity of iterations and an edge distance error according to an embodiment of this application.

FIG. 7 is a schematic diagram of a relationship between an edge distance error and a complexity total variation according to an embodiment of this application.

FIG. 8 is a schematic structural diagram of an apparatus for determining a parameter of a layout quality detection tool according to an embodiment of this application.

FIG. 9 is a schematic structural diagram of a terminal device according to an embodiment of this application.

FIG. 10 is a schematic structural diagram of a server according to an embodiment of this application.

### DESCRIPTION OF EMBODIMENTS

To make the objectives, technical solutions, and advantages of this application clearer, the following further describes implementations of this application in detail with reference to the accompanying drawings.

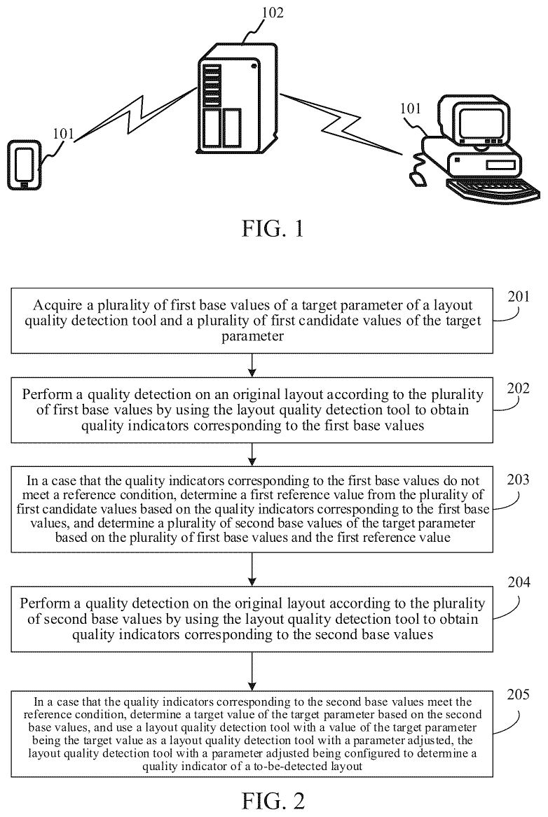

FIG. 1 is a schematic diagram of an implementation environment of a method for determining a parameter of a layout quality detection tool according to an embodiment of this application. As shown in FIG. 1, the implementation environment includes a terminal device 101 and a server 102. The method for determining a parameter of a layout quality detection tool in the embodiments of this application may be performed by the terminal device 101, or may be performed by the server 102, or may be jointly performed by the terminal device 101 and the server 102.

The terminal device 101 may be a smartphone, a video game console, a desktop computer, a tablet computer, a laptop portable computer, a smart TV, a smart in-vehicle device, a smart speech interaction device, a smart home appliance, or the like. The server 102 may be one server, or may be a server cluster formed by a plurality of servers, or may be any one of a cloud computing platform and a virtualization center. This is not limited in the embodiments of this application. The server 102 may be communicatively connected to the terminal device 101 by a wired network or a wireless network. The server 102 may have functions such as data processing, data storage, and data transmission and receiving. This is not limited in the embodiments of this application. A quantity of the terminal devices 101 and a quantity of the servers 102 are not limited, and one or more terminal devices or one or more servers may be used.

In the field of integrated circuit technologies, layouts tend to have greatly varied quality. Based on this, a layout quality detection tool usually determines quality indicators of candidate layouts. If a quality indicator of one candidate layout is greater than an indicator threshold, the candidate layout is determined as a target layout. The accuracy of the layout quality detection tool is closely related to the accuracy of selecting the target layout, and a parameter of the layout quality detection tool determines the accuracy of the layout quality detection tool. Therefore, how to determine the parameter of the layout quality detection tool becomes a problem that needs to be resolved urgently.

Embodiments of this application provide a method for determining a parameter of a layout quality detection tool. The method may be applied to the foregoing implementation environment. A value of a target parameter of a layout quality detection tool can be determined, thereby improving the accuracy of the layout quality detection tool. A flowchart of the method for determining a parameter of a layout quality detection tool according to an embodiment of this application in FIG. 2 is used as an example. For convenience of description, the terminal device 101 or the server 102 that performs the method for determining a parameter of a layout quality detection tool in the embodiments of this application is referred to as an electronic device. The method may be performed by the electronic device. As shown in FIG. 2, the method includes the following Operation 201 to Operation 205:
201: Acquire a plurality of first base values of a target parameter of a layout quality detection tool and a plurality of first candidate values of the target parameter.

In the embodiments of this application, the layout quality detection tool supports a quality detection of layouts. The layouts include, but not limited to, chip layouts, mask layouts, and wafer layouts. A chip layout is also referred to as an integrated circuit (IC) design layout. Generally, photolithography is performed on a mask based on a chip layout to obtain a mask layout, and photolithography is performed on a wafer based on the mask layout to obtain a wafer layout. The layout quality detection tool is not limited in the embodiments of this application. For example, the layout quality detection tool includes at least one of computer-aided design (CAD) software, electronic design automation (EDA) software, and the like.

The layout quality detection tool has a large number of parameters. Some of these parameters are configured and cannot be adjusted, and some parameters can be adjusted. A parameter that can be adjusted is referred to as an adjustable parameter. A value of the adjustable parameter is determined, so that the accuracy of the layout quality detection tool meets expectations. In the embodiments of this application, the target parameter is an adjustable parameter in the layout quality detection tool. The target parameter is not limited in the embodiments of this application. For example, the target parameter includes a learning rate, an iteration step, or the like. At least one target parameter is used. To be specific, one or more target parameters may be used. Target parameters have similar processing manners. Therefore, a parameter adjustment manner of the target parameter is described below without considering a quantity factor. To be specific, a process of determining a target value of the target parameter is described.

The electronic device may acquire the plurality of first base values of the target parameter and the plurality of first candidate values of the target parameter. In some embodiments, the plurality of first base values may also be referred to as multiple first base values, or referred to as at least two first base values; and the plurality of first candidate values may also be referred to as multiple first candidate values, or referred to as at least two first candidate values. Manners of acquiring any first base value and any first candidate value are not limited in the embodiments of this application. For example, the electronic device acquires inputted first base values and first candidate values, or the electronic device randomly generates first base values and first candidate values.

In a possible implementation, Operation 201 includes: acquiring a first value range of the target parameter; dividing the first value range into a plurality of first value intervals; and performing a sampling in the first value intervals to obtain the plurality of first base values and the plurality of first candidate values. A sampling is performed in the plurality of first value intervals to obtain the first base values and the first candidate values, which helps to improve the distribution uniformity of the first base values and the first candidate values, thereby ensuring the comprehensiveness of the first base values and the first candidate values.

In the embodiments of this application, the layout quality detection tool is configured on the electronic device, and a user may input the first value range of the target parameter in the layout quality detection tool. Alternatively, the electronic device may generate the first value range. Alternatively, the electronic device may acquire the configured first value range.

Next, the electronic device may divide the first value range into a plurality of first value intervals by using a Latin hypercube sampling (LHS) method. Any two adjacent first value intervals may partially overlap or not overlap, and the any two adjacent first value intervals may have the same length or different lengths. For any first value interval, at least one value is sampled from the first value interval, and any value is one first base value or one first candidate value. In this manner, at least one value of the first base values and the first candidate values is sampled from any first value interval.

In a possible implementation, the “performing a sampling in the first value intervals to obtain the plurality of first base values and the plurality of first candidate values” includes Operation 2011 to Operation 2013 (not shown in the figure).

Operation 2011: Perform the sampling in the first value intervals to obtain a plurality of first initial values of the target parameter.

In the embodiments of this application, the first value range is divided into a plurality of first value intervals by using the Latin Hypercube Sampling method, at least one value is sampled from any first value interval, and sampled values are used as the first initial values. In this manner, the plurality of first initial values are sampled from the first value intervals.

For example, K (K is a positive integer) target parameters are provided. For any target parameter, the first value range of the target parameter is divided into L (L is an integer greater than 1) first value intervals that have the same length and do not overlap. For any first value interval, one value is randomly sampled from the first value interval as one first initial value. Because one target parameter corresponds to the L first value intervals, L first initial values may be sampled for one target parameter, and a total of KL first initial values are sampled for the K target parameters.

In addition, in addition to inputting the first value range of the target parameter in the layout quality detection tool, the user may further input other information of the target parameter. For example, the user may further input a parameter type of the target parameter. Alternatively, the electronic device may acquire a parameter type of a configured target parameter. The parameter type of the target parameter may be a continuous parameter or a discrete parameter. The electronic device may sample at least one first initial value from any first value interval according to the parameter type of the target parameter. The first initial value sampled in this manner is a value that meets the parameter type of the target parameter, thereby ensuring the reliability of the first initial value.

In addition to sampling the plurality of first initial values from the first value ranges according to the Latin Hypercube Sampling method, a plurality of first initial values may be randomly sampled from the first value range according to a random sampling method. Compared with the random sampling method, during sampling according to the Latin Hypercube Sampling method, because the first initial values are sampled from the plurality of first value intervals obtained by dividing the first value range, the distribution of the first initial values may be more uniform, thereby ensuring the comprehensiveness of the first initial values.

Next, the plurality of first initial values may be classified into the plurality of first base values and the plurality of first candidate values in a random grouping manner. To be specific, for any first initial value, the first initial value may be randomly determined as one first base value or one first candidate value. Alternatively, in a clustering manner, the first base values and the first candidate values are determined from the plurality of first initial values. The clustering manner is described below.

Operation 2012: Cluster the plurality of first initial values to obtain a plurality of target clusters, any target cluster including at least one first initial value of the plurality of first initial values.

In the embodiments of this application, the plurality of first initial values may be clustered by using any clustering algorithm to obtain a plurality of target clusters. The clustering algorithm is not limited in the embodiments of this application. For example, the clustering algorithm includes any one of a K-means clustering algorithm, a density-based clustering algorithm, a model-based clustering algorithm, a probability-based clustering algorithm, and the like. An implementation of clustering the plurality of first initial values is described below by using the K-means clustering algorithm as an example.

First, initial cluster centers of a set quantity M (M is a positive integer) are acquired, and the set quantity M is configured for indicating a quantity of target clusters. A manner of determining M is not limited in the embodiments of this application. For example, the electronic device may acquire M inputted by the user, or the electronic device may randomly generate M, or the electronic device may acquire configured M. Any initial cluster center is a cluster center of an initial cluster. A manner of obtaining any initial cluster center is not limited in the embodiments of this application. For example, the electronic device may acquire M initial cluster centers inputted by the user, or the electronic device may randomly generate M initial cluster centers.

Then, based on the M initial cluster centers, the plurality of first initial values are clustered into M initial clusters. In some embodiments, for any first initial value, distances between the first initial value and the initial cluster centers are calculated. A manner of determining the distances is not limited in the embodiments of this application. For example, any distance determination manner of a Euclidean distance, a Manhattan distance, a Chebyshev distance, and the like may be used. The smallest distance is determined from the distances between the first initial value and the initial cluster centers, and the first initial value is classified into an initial cluster to which an initial cluster center corresponding to the smallest distance belongs. In this manner, the first initial values may be classified into the M initial clusters.

Next, for any initial cluster, a cluster center of the initial cluster is redetermined based on the first initial values included in the initial cluster. For convenience of differentiation, the redetermined cluster center is referred to as a first cluster center. When a difference between an initial cluster center of the initial cluster and the first cluster center of the initial cluster is less than a first threshold (for example, the first threshold is 0 or 0.0001), the cluster center of the initial cluster remains unchanged. In contrast, when the difference between the initial cluster center of the initial cluster and the first cluster center of the initial cluster is not less than the first threshold, the cluster center of the initial cluster has changed.

If none of cluster centers of the M initial clusters has changed, the algorithm converges. In this case, the initial clusters are used as the target clusters.

If a cluster center of at least one initial cluster of the M initial clusters has changed, the algorithm does not converge. In this case, the first cluster center is a cluster center of a first cluster, and the plurality of first initial values may be clustered into M first clusters based on M first cluster centers. For any first initial value, distances between the first initial value and the first cluster centers are calculated, the smallest distance is determined from the distances between the first initial value and the first cluster centers, and the first initial value is classified into an initial cluster to which a first cluster center corresponding to the smallest distance belongs. In this manner, the first initial values may be classified into the M first clusters. Subsequently, for any first cluster, a cluster center of the first cluster is redetermined based on the first initial values included in the first cluster. For convenience of differentiation, the redetermined cluster center is referred to as a second cluster center. When a difference between the first cluster center of the first cluster and the second cluster center of the first cluster is less than the first threshold, the cluster center of the first cluster remains unchanged. In contrast, when the difference between the first cluster center of the first cluster and the second cluster center of the first cluster is not less than the first threshold, the cluster center of the first cluster has changed.

If none of cluster centers of the M first clusters has changed, the algorithm converges. In this case, the first clusters are used as the target clusters.

If a cluster center of at least one first cluster of the M first clusters has changed, the algorithm does not converge. In this case, the second cluster center is a cluster center of a second cluster, and the plurality of first initial values may be clustered into M second clusters based on M second cluster centers. An implementation of clustering the plurality of first initial values into M second clusters is similar to the implementations of “clustering the plurality of first initial values into the M initial clusters” and “clustering the plurality of first initial values into the M first clusters” described above. Through the implementation similar to the foregoing content, the plurality of first initial values keep being clustered until the algorithm converges and M target clusters are obtained.

In brief, the clustering the plurality of first initial values by using the K-means clustering algorithm is equivalent to that according to a distance (for example, a Euclidean distance, a Manhattan distance, or a Chebyshev distance) between every two first initial values, the plurality of first initial values are classified into M clusters, to minimize a distance between any two first initial values that belong to the same cluster and maximize a distance between any two first initial values that belong to different clusters. When cluster centers of the M clusters no longer change, the K-means clustering algorithm converges, to eventually obtain the M clusters. The M clusters are the M target clusters discussed above.

In some embodiments, the K-means clustering algorithm converges, which is equivalent to minimizing a square error. In some embodiments, the square error is determined according to the following Formula (1).

$$error = {\sum }_{i = 1}^{M} {\sum }_{x ∈ {C}_{i}} {\vert x - {μ}_{i} \vert}^{2} \qquad Formula ( 1 )$$

$${μ}_{i} = \frac{1}{\vert {C}_{i} \vert} {\sum }_{x ∈ {C}_{i}} x$$

error represents the square error, M represents a quantity of cluster centers, Cᵢ represents an i^{th} cluster center, x represents a first initial value in Cᵢ, μᵢ represents a cluster center of Cᵢ, and |Cᵢ| represents a quantity of first initial values in Cᵢ.

As can be learned from Formula (1), the square error represents a square of a distance between each first initial value and a cluster center of a cluster. The square error can be minimized by adjusting the cluster center continuously, so that the K-means clustering algorithm converges, to eventually obtain the M target clusters.

Operation 2013: For any target cluster in the plurality of target clusters, select the first base values from the first initial values included in the any target cluster, and determine the first initial values other than the first base values in the any target cluster as the first candidate values.

In the embodiments of this application, at least one first initial value may be randomly selected from the first initial values included in the any target cluster as the first base value. Alternatively, the cluster center of the target cluster may be redetermined based on the first initial values included in any target cluster. For convenience of description, the redetermined cluster center of the target cluster is referred to as a target cluster center. Distances between first initial values in any target cluster and a target cluster center of the target cluster are calculated. At least one distance not greater than a second threshold is determined from the distances between the first initial values in the any target cluster and the target cluster center of the target cluster. First initial values corresponding to distances not greater than the second threshold are determined as the first base values. One or more first base values are selected from first initial values included in any target cluster. In other words, at least one first base value is determined from the first initial values included in the any target cluster.

The second threshold is not limited in the embodiments of this application. For example, the second threshold is a value determined empirically, or the second threshold is the smallest value in the distances between the first initial values in the target cluster and the target cluster center of the target cluster. When the second threshold is the smallest value in the distances between the first initial values in the target cluster and the target cluster center of the target cluster, one first base value may be determined based on one target cluster, and the first base value is a first initial value closest to a target cluster center in the target cluster.

In some embodiments, a manner of selecting the first base values from the first initial values included in the any target cluster may be: calculating distances between first initial values in any target cluster and a target cluster center of the target cluster, and determining at least one distance not less than a third threshold from the distances between the first initial values in the any target cluster and the target cluster center of the target cluster. First initial values corresponding to distances not less than the third threshold are determined as the first base values. For example, the third threshold is a value determined empirically, or the third threshold is the largest value in the distances between the first initial values in the target cluster and the target cluster center of the target cluster. When the third threshold is the largest value in the distances between the first initial values in the target cluster and the target cluster center of the target cluster, one first base value may be determined based on one target cluster, and the first base value is a first initial value farthest from a target cluster center in the target cluster.

In the foregoing manner, the first base value may be determined from the first initial values included in the target clusters. Next, the first initial values other than the first base values in the target clusters are determined as the first candidate values. The first base values are determined in a clustering manner, to improve the accuracy of the first base values, so that the efficiency of determining a target value can be increased.

Operation 202: Perform a quality detection on an original layout according to the plurality of first base values by using the layout quality detection tool to obtain quality indicators corresponding to the first base values.

Because the layout quality detection tool supports a quality detection of layouts, the layout quality detection tool may be determined by making the target parameter include any first base value, an original layout is inputted into the layout quality detection tool, and the layout quality detection tool performs a quality detection on the original layout to obtain a quality indicator of the original layout corresponding to the first base value. The original layout is a layout that meets a layout quality standard specified in the field of chips, and includes, but not limited to, a chip layout, a mask layout, and a wafer layout. Because the target parameter includes the plurality of first base values, a result of performing the quality detection on the original layout includes quality indicators of original layouts corresponding to the first base values. The quality indicator corresponding to the first base value in this embodiment of this application is the quality indicator of the original layout corresponding to the first base value.

For any first base value of the plurality of first base values, the quality indicator of the original layout corresponding to the first base value is configured for describing the quality of the original layout determined by using the layout quality detection tool when the target parameter of the layout quality detection tool includes the first base value.

Various types of indicators are configured for describing the quality of the original layout. To be specific, in the embodiments of this application, any first base value corresponds to at least one quality indicator, any quality indicator corresponding to the first base value is configured for describing the quality of the original layout in an aspect determined by using the layout quality detection tool when the target parameter of the layout quality detection tool includes the first base value. Any two quality indicators corresponding to any first base value describe quality of the original layout in different aspects.

For example, a mask complexity of the original layout may reflect the quality of the original layout. Generally, when the mask complexity of the original layout is lower, the quality of the original layout is higher. Therefore, any quality indicator corresponding to the any first base value may be a mask complexity corresponding to the first base value. The quality of the original layout is described through the mask complexity. The mask complexity corresponding to the first base value is negatively correlated with the original layout. To be specific, when the mask complexity corresponding to the first base value is smaller, the quality of the original layout is higher.

In another example, an edge distance error of the original layout may reflect the quality of the original layout. Generally, when the edge distance error of the original layout is lower, the quality of the original layout is higher. Therefore, any quality indicator corresponding to the any first base value may be an edge distance error corresponding to the first base value. The quality of the original layout is described through the edge distance error. The edge distance error corresponding to the first base value is negatively correlated with the original layout. To be specific, when the edge distance error corresponding to the first base value is smaller, the quality of the original layout is higher.

In a possible implementation, Operation 202 includes: processing the original layout according to the plurality of first base values by using the layout quality detection tool to obtain predicted layouts corresponding to the first base values, and determining the quality indicators corresponding to the first base values based on the predicted layouts corresponding to the first base values.

In the embodiments of this application, when the target parameter includes any first base value, the original layout is inputted into the layout quality detection tool, and the layout quality detection tool processes the original layout to obtain a predicted layout corresponding to the first base value. In some embodiments, the layout quality detection tool includes a photoresist model. The photoresist model may simulate a photolithography device in an actual scenario to perform photolithography on the original layout to obtain the predicted layout.

In other words, if the original layout is a chip layout, the layout quality detection tool performs photolithography on the chip layout. To be specific, the layout quality detection tool simulates a process of the photolithography device performing photolithography on a mask based on the chip layout to obtain a mask layout, and the mask layout is the predicted layout. If the original layout is a mask layout, or the original layout is a chip layout and the layout quality detection tool obtains a mask layout based on the chip layout, the layout quality detection tool may perform photolithography on the mask layout. To be specific, the layout quality detection tool simulates a process of the photolithography device performing photolithography on a wafer based on the mask layout to obtain a wafer layout, and the wafer layout is the predicted layout.

In the embodiments of this application, for any first base value, the layout quality detection tool may analyze a pattern of a predicted layout corresponding to the any first base value, and an analysis result is used as the quality indicator of the original layout corresponding to the first base value. Because of an interference effect and a diffraction effect in the process of photolithography, an error exists in the pattern of the predicted layout, so that the layout quality detection tool can analyze quality of the predicted layout based on the pattern of the predicted layout to obtain an analysis result. The analysis result can reflect the quality of the original layout and can reflect the quality of the predicted layout. A manner of analyzing the pattern by the layout quality detection tool is not limited in the embodiments of this application.

In some embodiments, if the original layout is a chip layout and the predicted layout is a wafer layout, for any first base value, the layout quality detection tool determines an error between the original layout and the predicted layout corresponding to the first base value. In some embodiments, pixels in the predicted layout correspond one-to-one to pixels in the original layout. In other words, any pixel in the predicted layout has a corresponding pixel in the original layout. The layout quality detection tool determines pixel differences between the pixels in the predicted layout and corresponding pixels in the original layout, and a sum value, an average value, or the like of these pixel differences is determined as the error between the predicted layout and the original layout. Alternatively, the layout quality detection tool extracts a feature of the predicted layout and a feature of the original layout, and uses a feature distance between the feature of the predicted layout and the feature of the original layout as the error between the predicted layout and the original layout.

Next, based on the error between the original layout and the predicted layout corresponding to the any first base value, the quality indicator of the original layout corresponding to the first base value (i.e., the quality indicator corresponding to the first base value) is determined. For example, the error between the original layout and the predicted layout corresponding to the any first base value is used as the quality indicator of the original layout corresponding to the first base value, or the error between the original layout and the predicted layout corresponding to the any first base value is weighted to obtain the quality indicator of the original layout corresponding to the first base value.

Theoretically, if the accuracy of the layout quality detection tool is 100%, the error between the predicted layout and the original layout is 0, and if the accuracy of the layout quality detection tool is 0, the error between the predicted layout and the original layout is 100%. Therefore, when the layout quality detection tool is more accurate, the error between the predicted layout and the original layout is smaller. In other words, the error between the predicted layout and the original layout may reflect the accuracy of the layout quality detection tool. The quality indicators of the original layouts corresponding to the first base values are calculated through errors between the original layout and the predicted layouts corresponding to the first base values, so that the quality indicators of the original layouts corresponding to the first base values can also reflect the accuracy of the layout quality detection tool. In this way, a value of the parameter of the layout quality detection tool can be adjusted to be more accurate based on the quality indicators of the original layouts corresponding to the first base values, thereby ensuring the accuracy of the layout quality detection tool.

In addition, the layout quality detection tool can directly determine the quality indicators of the original layouts based on the original layouts without simulating a photolithography device in an actual scenario. In other words, when the target parameter includes any first base value, the layout quality detection tool may analyze a pattern of an original layout to obtain a quality indicator of the original layout corresponding to the first base value. A manner of analyzing the pattern of the original layout by the layout quality detection tool is not limited in the embodiments of this application.

Operation 203: When the quality indicators corresponding to the first base values do not meet a reference condition, determine a first reference value from the plurality of first candidate values based on the quality indicators corresponding to the first base values, and determine a plurality of second base values of the target parameter based on the plurality of first base values and the first reference value.

That the quality indicators corresponding to the first base values do not meet a reference condition may be that a quality indicator corresponding to at least one first base value of the first base values does not meet the reference condition. To be specific, that the quality indicators corresponding to the first base values do not meet a reference condition may be that quality indicators corresponding to some first base values or all first base values of the first base values do not meet the reference condition. That a quality indicator corresponding to any first base value does not meet the reference condition is not limited in the embodiments of this application. For example, it may be determined, based on a quality indicator corresponding to any first base value and a reference threshold, whether the quality indicator corresponding to the first base value meets the reference condition. The reference threshold is set empirically, or is flexibly adjusted according to an application scenario. This is not limited in the embodiments of this application.

In some embodiments, if the quality indicator is negatively correlated with the quality of the original layout, for example, the quality indicator is a mask complexity, an edge distance error, or the like, when a quality indicator corresponding to any first base value is greater than the reference threshold, it is determined that a quality indicator corresponding to the first base value does not meet the reference condition; and when a quality indicator corresponding to any first base value is not greater than the reference threshold, it is determined that a quality indicator corresponding to the first base value meets the reference condition. If the quality indicator is positively correlated with the quality of the original layout, when a quality indicator corresponding to any first base value is less than the reference threshold, it is determined that a quality indicator corresponding to the first base value does not meet the reference condition; and when a quality indicator corresponding to any first base value is not less than the reference threshold, it is determined that a quality indicator corresponding to the first base value meets the reference condition.

Alternatively, the quality indicators corresponding to the first base values are determined in an iterative calculation manner. A quantity of iterations for determining the quality indicators corresponding to the first base values may be acquired. If the quantity of iterations is less than a quantity threshold, it is determined that the quality indicators corresponding to the first base values do not meet the reference condition. If the quantity of iterations is not less than the quantity threshold, it is determined that the quality indicators corresponding to the first base values meet the reference condition. The quantity threshold is set empirically, or is flexibly adjusted according to an application scenario. This is not limited in the embodiments of this application.

In the embodiments of this application, a quantity of the first base values is M, and a quantity of the first candidate values is L-M. Quality indicators corresponding to the M first base values may be sequentially denoted as (y₁, . . . , yₘ, . . . , y_{M}). When a quality indicator in (y₁, . . . , yₘ, . . . , y_{M}) does not meet the reference condition, the first reference value may be determined from the L−M first candidate values based on (y₁, . . . , yₘ, . . . , y_{M}). M is an integer greater than 1, and L−M is an integer greater than 1.

In a possible implementation, the “determining a first reference value from the plurality of first candidate values based on the quality indicators corresponding to the first base values” in Operation 203 includes Operation 2031 and Operation 2032 (not shown in the figure). One first reference value may be used, or a plurality of first reference values may be used. In other words, at least one first reference value is used. To be specific, at least one first reference value is determined from the plurality of first candidate values based on the quality indicators corresponding to the first base values, and the plurality of second base values of the target parameter are determined based on the plurality of first base values and the at least one first reference value.

Operation 2031: Determine reference indicators of the first candidate values based on the quality indicators corresponding to the first base values, a reference indicator of any first candidate value being configured for describing a case that a quality indicator meets the reference condition when a quality detection is performed on the original layout by using the layout quality detection tool when the target parameter includes the any first candidate value.

In the embodiments of this application, the quality indicators corresponding to the first base values may be denoted as (y₁, . . . , yₘ, . . . , y_{M}). Reference indicators of the L−M first candidate values are determined based on (y₁, . . . , yₘ, . . . , y_{M}). In some embodiments, a reference indicator of any first candidate value may be an expected improvement (EI) value. The expected improvement value reflects an improvement of the accuracy of the layout quality detection tool when the target parameter includes the first candidate value.

When a quality detection is performed on the original layout by using the layout quality detection tool, the quality indicator of the original layout may be obtained, and the quality indicator of the original layout reflects the accuracy of the layout quality detection tool. When the quality indicator is closer to the reference condition, the accuracy of the layout quality detection tool can be better improved. Therefore, an expected improvement of any first candidate value may reflect a possibility that a quality indicator meets the reference condition when a quality detection is performed on the original layout by using the layout quality detection tool when the target parameter includes the first candidate value. When the expected improvement value of the any first candidate value is larger, the possibility is higher.

In some embodiments, Operation 2031 includes Operation S1 and Operation S2 (not shown in the figure).

Operation S1: Determine a first mapping relationship based on the first base values and the quality indicators corresponding to the first base values, the first mapping relationship being configured for describing a mapping relationship between the first base values and statistical information of a statistical distribution when the quality indicators corresponding to the first base values meets the statistical distribution.

In the embodiments of this application, the first mapping relationship may be determined based on the M first base values and the quality indicators (y₁, . . . , yₘ, . . . , y_{M}) corresponding to the M first base values. (y₁, . . . , yₘ, . . . , y_{M}) meet a statistical distribution. The first mapping relationship is configured for describing a mapping relationship between the M first base values and the statistical information of the statistical distribution.

The statistical distribution is not limited in the embodiments of this application. For example, the statistical distribution is a Gaussian distribution, a chi-squared distribution, an F distribution, or the like. Different statistical distributions correspond to different statistical information. The statistical information is a parameter configured for determining a statistical distribution. For example, statistical information of a Gaussian distribution includes a mean value and a variance.

In some embodiments, M Gaussian process (GP) regression models may be determined based on the M first base values and the quality indicators (y₁, . . . , yₘ, . . . , y_{M}) corresponding to the M first base values. An m^{th} Gaussian process regression model is configured for describing a mapping relationship between an m^{th} first base value and a mean value and a variance of a Gaussian distribution when a quality indicator yₘ corresponding to the m^{th} first base value meets the Gaussian distribution. In this case, the first mapping relationship is described through the M Gaussian process regression models.

For the m^{th} Gaussian process regression model, because the mean value and the variance of the Gaussian distribution may reflect yₘ, the m^{th} Gaussian process regression model may reflect a mapping relationship between the m^{th} first base value and the corresponding quality indicator yₘ. yₘ is described through a Gaussian process algorithm, and the m^{th} Gaussian process regression model is obtained. The model may be represented as: GP(μm(x), σₘ(x)). x represents the target parameter, GP represents the Gaussian distribution that the corresponding quality indicator yₘ meets when the target parameter is the m^{th} first base value, μm(x) is the mean value of the Gaussian distribution, and σₘ(x) is the variance of the Gaussian distribution. In some embodiments, the variance of the Gaussian distribution is also referred to as an uncertainty of the Gaussian distribution.

In some embodiments, the Gaussian process regression model may describe root mean square errors of the quality indicators corresponding to the first base values, to be specific, Error (x)˜GP (m(x), k(x,x′)). Error (x) represents the mean square errors of the corresponding quality indicators when the target parameter x includes the first base values, m(x) is a mean value function of the target parameter x, and k(x, x′) is a kernel function related to the target parameter x and another parameter x′ other than the target parameter x in the layout quality detection tool. In the embodiments of this application, an n-dimensional square exponential function is used as the kernel function, and the kernel function may be denoted as:

$$k ( x , {x}^{′} ) = exp \{ - \frac{{\sum }_{i = 1}^{n} {\vert {x}_{i} - {x}_{i}^{′} \vert}^{2}}{{σ}_{i}^{2}} \} .$$

exp represents an exponential function with the natural constant e as the base, Σ is a summation symbol, xᵢ represents an i^{th} first base value of the target parameter x, xᵢ′ represents an i^{th} value of another parameter, n is a dimension of x, and σᵢ² is a hyperparameter obtained through maximum-likelihood estimation.

The first mapping relationship may be described through the M Gaussian process regression models. The M Gaussian process regression models are a set the meets a joint Gaussian distribution. In other words, on the premise that the quality indicators corresponding to the first base values meet the Gaussian distribution, the Gaussian process regression models corresponding to the first base values are determined, to determine the first mapping relationship.

Operation S2: For any first candidate value of the first candidate values, determine statistical information corresponding to the any first candidate value based on the any first candidate value and the first mapping relationship, and determine the reference indicator of the any first candidate value based on the statistical information corresponding to the any first candidate value.

In the embodiments of this application, the first mapping relationship can reflect a mapping relationship between the first base values and statistical information. In other words, the first mapping relationship may map any first base value into corresponding statistical information. Based on this, through the first mapping relationship, any first candidate value may be mapped into statistical information corresponding to the first candidate value.

Next, a reference indicator of any first candidate value is calculated by using the statistical information corresponding to the first candidate value. In the embodiments of this application, a calculation manner of the reference indicator of the first candidate value is not limited. For example, the statistical information corresponding to the first candidate value is weighted to obtain the reference indicator of the first candidate value, or the reference indicator of the first candidate value is determined according to Operation S21 to Operation S23 discussed below.

In some embodiments, the statistical information corresponding to any first candidate value includes a mean value and a variance. In some embodiments, the first mapping relationship includes a Gaussian process regression model. As can be learned from the foregoing description of the model, the model may predict a first candidate value to obtain a mean value μm(x) and a variance σₘ(x) corresponding to the first candidate value. In this case, the “determining the reference indicator of the any first candidate value based on the statistical information corresponding to the any first candidate value” in Operation S2 includes Operation S21 to Operation S23 (not shown in the figure).

Operation S21: Determine a reference quality indicator from the quality indicators corresponding to the first base values.

In the embodiments of this application, one quality indicator is randomly determined from the quality indicators corresponding to the first base values, or the reference quality indicator is determined according to Implementation A1 or Implementation A2 discussed below.

In Implementation A1, any first base value corresponds to one quality indicator. In this case, Operation S21 includes: determining the smallest quality indicator from the quality indicators corresponding to the first base values, and determining the smallest quality indicator as the reference quality indicator.

In the embodiments of this application, for single-target minimization optimization, one quality indicator is configured for describing an original layout. In this case, one first base value corresponds to one quality indicator. For example, the quality indicator of the original layout is a mask complexity of the original layout, and one first base value corresponds to one mask complexity. The single-target minimization optimization is optimizing a quality indicator corresponding to an aspect obtained when the layout quality detection tool performs a quality detection on the original layout in the aspect. In other words, the single-target minimization optimization is optimizing a single quality indicator in the layout quality detection tool.

Based on this, the M first base values correspond to M quality indicators, which are respectively (y₁, . . . , yₘ, . . . , y_{M}). The smallest quality indicator may be determined from the quality indicators corresponding to the first base values, and the smallest quality indicator is determined as the reference quality indicator. To be specific, the reference quality indicator is fₘ=min (y₁, . . . , yₘ, . . . , y_{M}).

In Implementation A2, any first base value corresponds to a plurality of quality indicators. In this case, Operation S21 includes Operation S211 to Operation S213 (not shown in the figure).

In the embodiments of this application, for multiple-target minimization optimization, a plurality of quality indicators are configured for describing an original layout. In this case, one first base value corresponds to a plurality of quality indicators. For example, the quality indicator of the original layout includes a mask complexity of the original layout and an edge distance error of the original layout, and one first base value corresponds to one mask complexity and one edge distance error. The multiple-target minimization optimization is optimizing a quality indicator corresponding to a plurality of aspects obtained when the layout quality detection tool performs a quality detection on the original layout in the aspects. In other words, the multiple-target minimization optimization is optimizing a plurality of quality indicators in the layout quality detection tool.

The layout quality detection tool has a large number of adjustable parameters. These adjustable parameters affect a quality detection result of a layout. Generally, a plurality of quality indicators are configured for representing layout quality, and a balance relationship exists between the quality indicators. For example, when a mask error is smaller, a mask complexity is higher, and manufacturing difficulty is higher. Therefore, the mask complexity and the mask error balance out each other. A Pareto effect is formed between the mask complexity and the mask error, and a Pareto optimal solution set needs to be determined. In some embodiments, the Pareto optimal solution set is also referred to as a Pareto front. When the focus is on a quality indicator, a solution inclining toward the quality indicator on the Pareto front may be determined.

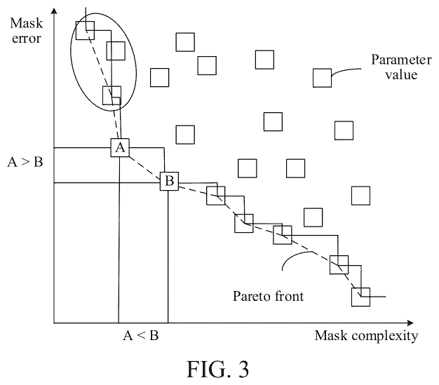

FIG. 3 is a schematic diagram of a Pareto front between a mask error and a mask complexity according to an embodiment of this application. As can be learned from FIG. 3, on the Pareto front, if a mask error A is greater than a mask error B, a mask complexity A is less than a mask complexity B. A and B are data on the Pareto front. The data includes a mask error and a mask complexity. When more focus is on the mask error, data (that is, parameter values enclosed by the ellipse in FIG. 3) inclining toward the mask error on the Pareto front may be determined.

Operation S211: For any quality indicator of the plurality of quality indicators, determine a maximum value and a minimum value of the any quality indicator from the any quality indicators corresponding to the first base values.

In the embodiments of this application, assuming that a total of M (M is a positive integer)) quality indicators are used, each first base value corresponds to M quality indicators. An example in which any first base value is the i^{th} first base value and any quality indicator is an m^{th} quality indicator is used, and the m^{th} quality indicator corresponding to the i^{th} first base value may be denoted as y_{m,i}. A maximum value yₘ^{max} of the m^{th} quality indicator and a minimum value yₘ^{min} of the m^{th} quality indicator may be determined from the m^{th} quality indicators corresponding to the first base values.

Operation S212: For the any quality indicator corresponding to the any first base value, determine a priority indicator of the any quality indicator corresponding to the any first base value based on a first selected quality indicator, a weight of the first selected quality indicator, and the maximum value and the minimum value of the first selected quality indicator, the first selected quality indicator being at least one quality indicator of the plurality of quality indicators corresponding to the any first base value, the first selected quality indicator including the any quality indicator corresponding to the any first base value.

In the embodiments of this application, the electronic device may acquire a weight of any quality indicator. The weight is configured for describing the importance of the quality indicator. In other words, when the weight of the any quality indicator is larger, the quality indicator is more important, and can better reflect the quality of the original layout. A manner of acquiring the weight of any quality indicator is not limited in the embodiments of this application. For example, the electronic device may acquire a weight of any inputted quality indicator, or the electronic device may determine a weight of any quality indicator according to a quantity of quality indicators. For example, two quality indicators are used, and a weight of each quality indicator is 0.5.

In some embodiments, the quality indicators are sorted to obtain the sorted quality indicators. For example, the quality indicators may be sorted in a manual sorting manner, or the quality indicators may be sorted in a random sorting manner. When a priority indicator of any quality indicator corresponding to any first base value is calculated, calculation may be performed by using the quality indicator and quality indicators sorted following the quality indicator. The quality indicators used to calculate the priority indicator of the any quality indicator corresponding to the any first base value are referred to as first selected quality indicators. In other words, for the first selected quality indicator (i.e., at least one quality indicator of the plurality of quality indicators corresponding to the any first base value) in Operation S212, when the any quality indicator corresponding to the any first base value is the last quality indicator after sorting, the first selected quality indicator (i.e., at least one quality indicator of the plurality of quality indicators corresponding to the any first base value) includes the any quality indicator corresponding to the any first base value. When the any quality indicator corresponding to the any first base value is not the last quality indicator after sorting, the first selected quality indicator (i.e., at least one quality indicator of the plurality of quality indicators corresponding to the any first base value) includes the any quality indicator corresponding to the any first base value and quality indicators sorted following the any quality indicator corresponding to the any first base value.

Assuming that each first base value corresponds to M quality indicators, an example in which any first base value is the i^{th} first base value and any quality indicator is an m^{th} quality indicator is used, and at least one quality indicator in a plurality of quality indicators corresponding to the i^{th} first base value includes an m^{th} to an M^{th} quality indicators corresponding to the i^{th} first base value.

In the embodiments of this application, the electronic device may determine a priority indicator of the m^{th} quality indicator corresponding to the i^{th} first base value according to the following Formula (2).

$${d}_{i} = {\sum }_{m}^{M} {ω}_{m} \frac{{y}_{m , i} - {y}_{m}^{max}}{{y}_{m}^{max} - {y}_{m}^{min}} \qquad Formula ( 2 )$$

dᵢ represents the priority indicator of the m^{th} quality indicator corresponding to the i^{th} first base value. M represents the quantity of quality indicators. ωₘ represents a weight of the m^{th} quality indicator, y_{m,i} represents the m^{th} quality indicator corresponding to the i^{th} first base value, yₘ^{max} represents the maximum value of the m^{th} quality indicator, and yₘ^{min} represents the minimum value of the m^{th} quality indicator.

In Formula (2), when the priority indicator of the m^{th} quality indicator corresponding to the i^{th} first base value is determined, the m^{th} to the M^{th} quality indicators corresponding to the i^{th} first base value need to be used. As can be learned, Formula (2) is about the priority indicator of the m^{th} quality indicator corresponding to the i^{th} first base value determined on the premise that the M quality indicators balance out each other, thereby improving the accuracy of the priority of the quality indicator. When the reference quality indicator is determined based on the priority indicator of the quality indicator in Operation S213, the reference quality indicator approximates to a Pareto optimal solution of the M quality indicators, thereby improving the accuracy of the reference quality indicator.

In some embodiments, after the quality indicators are sorted, when a priority indicator of any quality indicator corresponding to any first base value is calculated, calculation may be performed by using the quality indicator and quality indicators sorted before the quality indicator. In other words, for the first selected quality indicator (i.e., at least one quality indicator of the plurality of quality indicators corresponding to the any first base value) in Operation S212, when the any quality indicator corresponding to the any first base value is the first quality indicator after sorting, the first selected quality indicator (i.e., at least one quality indicator of the plurality of quality indicators corresponding to the any first base value) includes the any quality indicator corresponding to the any first base value. When the any quality indicator corresponding to the any first base value is not the first quality indicator after sorting, the first selected quality indicator (i.e., at least one quality indicator of the plurality of quality indicators corresponding to the any first base value) includes the any quality indicator corresponding to the any first base value and quality indicators sorted before the any quality indicator corresponding to the any first base value.

Assuming that each first base value corresponds to M quality indicators, an example in which any first base value is the i^{th} first base value and any quality indicator is an m^{th} quality indicator is used, and at least one quality indicator in a plurality of quality indicators corresponding to the i^{th} first base value includes the first to the m^{th} quality indicators corresponding to the i^{th} first base value.

Operation S213: Determine the reference quality indicator from the quality indicators corresponding to the first base values based on priority indicators of the quality indicators corresponding to the first base values.

In the embodiments of this application, the priority indicators of the quality indicators corresponding to the first base values may be determined in the manner in Operation S212. Next, the smallest priority indicator is selected from these priority indicators, and a quality indicator corresponding to the smallest priority indicator is determined as the reference quality indicator. In other words, the reference quality indicator fₘ is a quality indicator corresponding to the smallest dᵢ. Alternatively, a priority indicator not greater than a priority threshold is selected from these priority indicators, and a quality indicator corresponding to the priority indicator not greater than the priority threshold is determined as the reference quality indicator. In this manner, the reference quality indicator is determined from the quality indicators corresponding to the first base values.

For example, the quality indicators corresponding to the first base values are used as a training set, and the reference quality indicator fₘ determined in Implementation A2 is an evaluation result corresponding to the most balanced parameter of a Pareto front of the training set. The Pareto front is calculated in the training set, and a weighted Euclidean distance dᵢ is calculated on the Pareto front. The reference quality indicator fₘ is determined through dᵢ, so that the accuracy of fₘ can be improved, thereby improving the accuracy of the reference indicator of the first candidate value.

Operation S22: Determine a normal distribution function of the any first candidate value based on the reference quality indicator and the mean value and the variance that correspond to the any first candidate value.

In the embodiments of this application, a difference between the reference quality indicator and the mean value that corresponds to the any first candidate value may be determined; and a quotient of the difference by the variance corresponding to the any first candidate value may be used as the normal distribution function of the any first candidate value. In other words, the difference between the reference quality indicator and the mean value that corresponds to the any first candidate value may be divided by the variance corresponding to the any first candidate value to obtain the normal distribution function of the any first candidate value. In some embodiments, a normal distribution function zₘ of the any first candidate value may be represented as: zₘ=(fₘ−μₘ(x))/σₘ(x). fₘ is the reference quality indicator, μₘ(x) is the mean value corresponding to the any first candidate value, and σₘ(x) is the variance corresponding to the any first candidate value.

Operation S23: Determine the reference indicator of the any first candidate value based on the variance corresponding to the any first candidate value, the normal distribution function corresponding to the any first candidate value, and a cumulative density function and a probability density function of the normal distribution function corresponding to the any first candidate value.

In the embodiments of this application, the normal distribution function corresponding to the any first candidate value may be multiplied by the cumulative density function of the normal distribution function to obtain a multiplication result. The multiplication result is added to the probability density function of the normal distribution function corresponding to the any first candidate value to obtain an addition result. The addition result is multiplied by the variance corresponding to the any first candidate value to obtain the reference indicator of the any first candidate value. In some embodiments, a reference indicator EIₘ(x) of the any first candidate value may be represented as: EIₘ(x)=σₘ(x [zₘΦ(zₘ)+φ(zₘ)]. σₘ(x) represents the variance corresponding to the any first candidate value, zₘ represents the normal distribution function of the any first candidate value, (zₘ) represents the cumulative density function of zₘ, and φ(zₘ) represents the probability density function of zₘ.

The reference indicator EIₘ(x) of the any first candidate value includes two items. The first item is σₘ(x)zₘΦ(zₘ). The item tends to search for a result better than a current optimal value, representing performing a local search in a detection process. The second item is σₘ(x)φ(zₘ). The item tends to search for an area with a higher uncertainty in a space in which the first candidate value is located, representing performing a global search in the detection process. The reference indicator of the any first candidate value is determined through the first item and the second item, to implement the local search and the global search in the detection process, thereby improving the accuracy of the reference indicator of the first candidate value.

The reference indicator of the first candidate value is determined by considering the statistical distribution and the statistical information, thereby ensuring the accuracy of the reference indicator of the first candidate value. In addition, in a process of determining the reference indicator of the first candidate value, in consideration of different cases that the first base value corresponds to one or more quality indicators, in the different cases, the reference indicator of the first candidate value is determined in different manners, so that the reliability of the manners of determining the reference indicator of the first candidate value is high, to further ensure the accuracy of the reference indicator of the first candidate value, thereby improving the accuracy of the eventually determined target value.

Operation 2032: Determine the first reference value from the plurality of first candidate values based on the reference indicators of the first candidate values.

In the embodiments of this application, in the manner in Operation 2031, the reference indicators of the first candidate values may be determined. For any first candidate value, it may be determined, based on the reference indicator of the first candidate value, whether the first candidate value may be used as the first reference value, to determine the first reference value from the plurality of first candidate values. In some embodiments, the first reference value is determined according to Implementation B1 or Implementation B2 below. For example, at least one first reference value is used. To be specific, the at least one first reference value is determined from the plurality of first candidate values based on the reference indicators of the first candidate values.

In Implementation B1, any first candidate value corresponds to one reference indicator. In this case, Operation 2032 includes: selecting a first candidate value with a reference indicator not less than a set indicator threshold from the plurality of first candidate values based on the reference indicators of the first candidate values as the first reference value.

For single-target minimization optimization, one quality indicator is used. According to the content related to the first mapping relationship in Operation S1, one first mapping relationship may be obtained. As can be learned from the content related to the reference indicator of the first candidate value in Operation S2, one first candidate value corresponds to one reference indicator.

For any first candidate value, if the reference indicator of the first candidate value is not less than the set indicator threshold, the first candidate value is used as the first reference value; and if the reference indicator of the first candidate value is less than the set indicator threshold, the first candidate value is not the first reference value. In this manner, the first reference value may be determined.

A manner of determining the set indicator threshold is not limited in the embodiments of this application. For example, the set indicator threshold is a value set empirically. Alternatively, the reference indicators of the first candidate values are sorted in descending order or in ascending order to obtain sorted reference indicators. An M^{th} (the set quantity) reference indicator after sorting is set as the set indicator threshold. In this case, it is equivalent to that a plurality of first candidate values are sorted in descending order of reference indicators, and the first candidate values of the set quantity at the top are selected as the first reference values; or it is equivalent to that a plurality of first candidate values are sorted in ascending order of reference indicators, and an M^{th} (the set quantity) first candidate value and first candidate values following the M^{th} (the set quantity) first candidate value are used as the first reference values.

In Implementation B2, any first candidate value corresponds to a plurality of reference indicators. In this case, Operation 2032 includes Operation 20321 to Operation 20324 (not shown in the figure).

For multiple-target minimization optimization, a plurality of quality indicators are used. As can be learned from the content related to the first mapping relationship in Operation S1, each quality indicator corresponds to one first mapping relationship. As can be learned from the content related to the reference indicator of the first candidate value in Operation S2, one reference indicator corresponding to one first candidate value may be determined through one first mapping relationship. Based on this, one first candidate value corresponds to a plurality of reference indicators.

Operation 20321: For any reference indicator of the plurality of reference indicators, determine a maximum value and a minimum value of the any reference indicator from the any reference indicators corresponding to the first candidate values.

In the embodiments of this application, assuming that a total of M (M is a positive integer)) reference indicators are used, each first candidate value corresponds to the M reference indicators. An example in which any first candidate value is an i^{th} first candidate value and any reference indicator is an m^{th} reference indicator is used, and the m^{th} reference indicator corresponding to the i^{th} first candidate value may be denoted as EI_{m,i}. A maximum value EIₘ^{max} of the m^{th} reference indicator and a minimum value EIₘ^{min} of the m^{th} reference indicator may be determined from the m^{th} reference indicators corresponding to the first candidate values.

Operation 20322: For any reference indicator corresponding to the any first candidate value, determine a priority indicator of the any reference indicator corresponding to the any first candidate value based on a selected reference indicator and a maximum value and a minimum value of the selected reference indicator, the selected reference indicator being at least one reference indicator of the plurality of reference indicators corresponding to the any first candidate value, the selected reference indicator including the any reference indicator corresponding to the any first candidate value.

In some embodiments, the reference indicators are sorted to obtain the sorted reference indicators. For example, the reference indicators may be sorted in a manual sorting manner, or the reference indicators may be sorted in a random sorting manner. When a priority indicator of any reference indicator corresponding to any first candidate value is calculated, calculation may be performed by using the reference indicator and reference indicators sorted following the reference indicator. A reference indicator used to calculate the priority indicator of the any reference indicator corresponding to the any first candidate value is referred to as a selected reference indicator. In other words, for the selected reference indicator (i.e., at least one reference indicator of the plurality of reference indicators corresponding to the any first candidate value) in Operation 20322, when the any reference indicator corresponding to the any first candidate value is the last reference indicator after sorting, the selected reference indicator (i.e., at least one reference indicator of the plurality of reference indicators corresponding to the any first candidate value) includes the any reference indicator corresponding to the any first candidate value. When the any reference indicator corresponding to the any first candidate value is not the last reference indicator after sorting, the selected reference indicator (i.e., at least one reference indicator of the plurality of reference indicators corresponding to the any first candidate value) includes the any reference indicator corresponding to the any first candidate value and reference indicators sorted following the any reference indicator corresponding to the any first candidate value.

Assuming that each first candidate value corresponds to M reference indicators, an example in which any first candidate value is an i^{th} first candidate value and any reference indicator is an m^{th} reference indicator is used, and at least one reference indicator in a plurality of reference indicators corresponding to the i^{th} first candidate value includes the m^{th} to an M^{th} reference indicators corresponding to the i^{th} first candidate value.

In the embodiments of this application, the electronic device may acquire a weight of any reference indicator. The weight is configured for describing the importance of the reference indicator. In other words, when the weight of the any reference indicator is larger, the reference indicator is more important. A manner of acquiring the weight of any reference indicator is not limited in the embodiments of this application. For example, the electronic device may acquire a weight of any inputted reference indicator, or the electronic device may determine a weight of any reference indicator according to a quantity of reference indicators. For example, two reference indicators are used, and a weight of each reference indicator is 0.5.

In some embodiments, the electronic device may determine a priority indicator of the m^{th} reference indicator corresponding to the i^{th} first candidate value according to the following Formula (3).

$${d}_{i}^{′} = {\sum }_{m}^{M} {ω}_{M - m} \frac{{EI}_{m , i} - {EI}_{m}^{max}}{{EI}_{m}^{max} - {EI}_{m}^{min}} \qquad Formula ( 3 )$$

dᵢ′ represents the priority indicator of the m^{th} reference indicator corresponding to the i^{th} first candidate value. M represents the quantity of reference indicators. ω_{M-m} represents a weight of the (M-m)^{th} reference indicator, EI_{m,i} represents the m^{th} reference indicator corresponding to the i^{th} first candidate value, EIₘ^{max} represents the maximum value of the m^{th} reference indicator, and EIₘ^{min} represents the minimum value of the m^{th} reference indicator.

In some embodiments, after the reference indicators are sorted, when a priority indicator of any reference indicator corresponding to any first candidate value is calculated, calculation may be performed by using the reference indicator and reference indicators sorted before the reference indicator. In other words, for the selected reference indicator (i.e., at least one reference indicator of the plurality of reference indicators corresponding to the any first candidate value) in Operation 20322, when the any reference indicator corresponding to the any first candidate value is the first reference indicator after sorting, the selected reference indicator (i.e., at least one reference indicator of the plurality of reference indicators corresponding to the any first candidate value) includes the any reference indicator corresponding to the any first candidate value. When the any reference indicator corresponding to the any first candidate value is not the first reference indicator after sorting, the selected reference indicator (i.e., at least one reference indicator of the plurality of reference indicators corresponding to the any first candidate value) includes the any reference indicator corresponding to the any first candidate value and reference indicators sorted before the any reference indicator corresponding to the any first candidate value.

Assuming that each first candidate value corresponds to M reference indicators, an example in which any first candidate value is an i^{th} first candidate value and any reference indicator is an m^{th} reference indicator is used, and at least one reference indicator in a plurality of reference indicators corresponding to the i^{th} first candidate value includes the first to the m^{th} reference indicators corresponding to the i^{th} first candidate value.

Operation 20323: Determine a target indicator from reference indicators corresponding to the first candidate values based on priority indicators of the reference indicators corresponding to the first candidate values.

In the embodiments of this application, the priority indicators of the reference indicators corresponding to the first candidate values may be determined in the manner in Operation 20322. Next, these priority indicators are sorted, and reference indicators corresponding to priority indicators before a specified position after sorting are determined as target indicators. Alternatively, these priority indicators are sorted, the sorted priority indicators are segmented into a plurality of segments of indicators randomly or at equal intervals, and one segment of indicators includes at least one priority indicator after sorting. For any indicator, the priority indicators included in the segment of indicators are sampled, and a reference indicator corresponding to a sampled priority indicator is determined as the target indicator. For example, the smallest priority indicator is sampled from the priority indicators included in one segment of indicators, and a reference indicator corresponding to the smallest priority indicator is determined as the target indicator. In this manner, the target indicators are sampled from the segment of indicators. One or more target indicators are used. In other words, at least one target indicator is used. To be specific, the at least one target indicator is determined from the reference indicators corresponding to the first candidate values based on the priority indicators of the reference indicators corresponding to the first candidate values.

Operation 20324: Determine a first candidate value corresponding to the target indicator as the first reference value.

In other words, for any target indicator, a first candidate value corresponding to the target indicator is determined as one first reference value. Because at least one target indicator is used, at least one first reference value may be determined in this manner.

For example, the reference indicators corresponding to the first candidate values are used as a training set, and the target indicator determined in Implementation B2 is an evaluation result corresponding to the most balanced parameter of a Pareto front of the training set. The Pareto front is calculated in the training set, and a weighted Euclidean distance dᵢ′ is calculated on the Pareto front. The reference quality indicator is determined through dᵢ′, so that the accuracy of the target indicator can be improved, thereby improving the accuracy of the first reference value.

Next, the plurality of second base values are determined based on the plurality of first base values and the first reference value. For example, one first base value may be one second base value, and one first reference value may be one second base value. In other words, the first base values and the first reference values may be used as the second base values. Alternatively, the any first base value is adjusted based on the first reference value to obtain an adjusted base value corresponding to the any first base value, and adjusted base values corresponding to the first base values are used as the plurality of second base values.

For example, at least one first reference value is used, and a manner of adjusting the any first base value based on the first reference value to obtain an adjusted base value corresponding to the any first base value may be: using an average value of the at least one first reference value as a first value, and adjusting the any first base value based on the first value to obtain the adjusted base value corresponding to the any first base value. For example, an average value of the first value and the any first base value is used as the adjusted base value corresponding to the any first base value. In another example, a weighted averaging is performed on the first value and the any first base value to obtain the adjusted base value corresponding to the any first base value. In a process of performing the weighted averaging on the first value and the any first base value, a weight corresponding to the first value and a weight corresponding to the any first base value may be set empirically, or flexibly adjusted according to an application scenario. This is not limited in the embodiments of this application.

In a process of determining the first reference value, in consideration of different cases that the first candidate value corresponds to one or more reference indicators, in the different cases, the first reference value is determined in different manners, so that the reliability of the manners of determining the first reference value is high, to further ensure the accuracy of the first reference value, thereby improving the accuracy of the eventually determined target value.

Operation 204: Perform a quality detection on the original layout according to the plurality of second base values by using the layout quality detection tool to obtain quality indicators corresponding to the second base values.

In the embodiments of this application, the layout quality detection tool is determined by making the target parameter include any second base value, an original layout is inputted into the layout quality detection tool, and the layout quality detection tool performs a quality detection on the original layout to obtain a quality indicator of the original layout corresponding to the second base value. At least one quality indicator is used. To be specific, any second base value corresponds to at least one quality indicator, and a result of performing the quality detection on the original layout includes quality indicators corresponding to the second base values. The quality indicator corresponding to the second base value in this embodiment of this application is the quality indicator of the original layout corresponding to the second base value.

An implementation of Operation 204 is similar to the implementation of Operation 202, and refer to the description of Operation 202. Details are not described herein again.

Operation 205: When the quality indicators corresponding to the second base values meet the reference condition, determine a target value of the target parameter based on the second base values, and use a layout quality detection tool with a value of the target parameter being the target value as a layout quality detection tool with a parameter adjusted, the layout quality detection tool with a parameter adjusted being configured to determine a quality indicator of a to-be-detected layout.

That the quality indicators corresponding to the second base values meet the reference condition is that quality indicators corresponding to all the second base values meet the reference condition. That a quality indicator corresponding to any second base value meets the reference condition is not limited in the embodiments of this application. For example, it is determined, based on a quality indicator corresponding to any second base value and a reference threshold, whether the quality indicator corresponding to the second base value meets the reference condition. Alternatively, a quantity of iterations for determining the quality indicators corresponding to the second base values is acquired, and it is determined, based on the quantity of iterations and the quantity threshold, whether the quality indicators corresponding to the second base values meet the reference condition.

Content of that the quality indicator corresponding to the any second base value meets the reference condition is similar to content of that the quality indicator corresponding to the any first base value meets the reference condition, and refer to the description of Operation 203. Details are not described herein again.

If the quality indicators corresponding to the second base values meet the reference condition, the second base values may be determined as the target values of the target parameter. Alternatively, for single-target minimization optimization, one second base value corresponds to one quality indicator, and according to the implementation principle of Implementation B1, a second base value with a quality indicator greater than or less than a set threshold may be selected from the plurality of second base values, and the selected second base value is used as the target value. For example, one second base value corresponds to one quality indicator configured for representing an edge distance error of the original layout, and a second base value with the smallest quality indicator is selected from the plurality of second base values as the target value. For the implementation principle of the foregoing content, refer to Implementation B1. Details are not described herein again.

For multiple-target minimization optimization, one second base value corresponds to a plurality of quality indicators. According to the implementation principle of Implementation B2, for any quality indicator of the plurality of quality indicators, a maximum value and a minimum value of the any quality indicator may be determined from the any quality indicators corresponding to the second base values. For the any quality indicator corresponding to the any second base value, a priority indicator of the any quality indicator corresponding to the any second base value is determined based on a second selected quality indicator and a maximum value and a minimum value of the second selected quality indicator, the second selected quality indicator being at least one quality indicator of the plurality of quality indicators corresponding to the any second base value, the second selected quality indicator including the any quality indicator corresponding to the any second base value. A target quality indicator is determined from the quality indicators corresponding to the second base values based on priority indicators of the quality indicators corresponding to the second base values; and a second base value corresponding to the target quality indicator is determined as the target value. One or more target quality indicators are used. In other words, at least one target quality indicator is used. To be specific, the at least one target quality indicator is determined from the quality indicators corresponding to the second base values based on the priority indicators of the quality indicators corresponding to the second base values. The target value determined in this manner is a value in a Pareto optimal solution set of the second base values. For the implementation principle of the foregoing content, refer to Implementation B2. Details are not described herein again.

Alternatively, for multiple-target minimization optimization, one second base value corresponds to a plurality of quality indicators. Through the annotation of the original layout, an indicator interval corresponding to the quality indicators of the original layouts is determined. For example, it is determined through manual annotation that the mask complexity of the original layout ranges from 0.2 to 0.6, and an edge error ranges from 0.1 to 0.3. If quality indicators corresponding to one second base value are within a corresponding indicator interval, the second base value is determined as the target value. In this manner, at least one target value of the target parameter may be determined.

In a possible implementation, the method in the embodiments of this application further includes Operation 206 to Operation 208 (not shown in the figure). Operation 206 to Operation 208 are performed after Operation 204.

Operation 206: When the quality indicators corresponding to the second base values do not meet the reference condition, determine a second reference value from a plurality of second candidate values based on the quality indicators corresponding to the second base values, and determine a plurality of third base values based on the plurality of second base values and the second reference value, the plurality of second candidate values including first candidate values other than the first reference values of the plurality of first candidate values.

In the embodiments of this application, the first candidate values other than the first reference values of the plurality of first candidate values may be used as the second candidate values. If the quality indicators corresponding to the second base values do not meet the reference condition, according to an implementation principle similar to that of Operation 203, the second reference value is determined from the second candidate values, and the third base values are determined based on the second base values and the second reference value. For this part of content, refer to the description of Operation 203. Details are not described herein again.

One or more second reference values are used. In other words, at least one second reference value is used. To be specific, at least one second reference value is determined from the plurality of second candidate values based on the quality indicators corresponding to the second base values, the plurality of third base values are determined based on the plurality of second base values and the at least one second reference value, the plurality of second candidate values including first candidate values other than the at least one first reference value of the plurality of first candidate values.

In some embodiments, the “determining a second reference value from a plurality of second candidate values based on the quality indicators corresponding to the second base values, and determining a plurality of third base values based on the plurality of second base values and the second reference value” in Operation 206 includes Operation 2061 to Operation 2065 (not shown in the figure).

Operation 2061: Adjust the first value range of the target parameter to obtain a second value range of the target parameter.

In the embodiments of this application, it may be flexibly selected according to an actual case to expand the first value range, to reduce the first value range, or not to adjust the first value range. When the first value range is expanded or reduced, the expanded or reduced first value range is a second value range.

In some embodiments, Operation 2061 includes: determining a first quality indicator with a quality indicator not greater than a first indicator threshold from the quality indicators corresponding to the first base values; determining a second quality indicator with a quality indicator not greater than a second indicator threshold from the quality indicators corresponding to the second base values; when the first quality indicator is less than the second quality indicator, reducing the first value range to obtain the second value range; and when the first quality indicator is greater than the second quality indicator, expanding the first value range to obtain the second value range.

The first indicator threshold and the second indicator threshold are not limited in the embodiments of this application. For example, the first indicator threshold and the second indicator threshold are values set empirically, or the first indicator threshold is the smallest quality indicator of the quality indicators corresponding to the first base values, and the second indicator threshold is the smallest quality indicator of the quality indicators corresponding to the second base values.

For the quality indicator corresponding to the any first base value, if the quality indicator is less than or equal to the first indicator threshold, the quality indicator is determined as the first quality indicator. In this manner, the at least one first quality indicator is determined from the quality indicators corresponding to the first base values. In the same manner, at least one second quality indicator is determined from the quality indicators corresponding to the second base values.

If the first indicator threshold is the smallest quality indicator of the quality indicators corresponding to the first base values, the first quality indicator is the smallest quality indicator of the quality indicators corresponding to the first base values. Similarly, the second quality indicator may be the smallest quality indicator of the quality indicators corresponding to the second base values.

Next, it is determined, based on the first quality indicators and the second quality indicators, whether to reduce or expand the first value range. In some embodiments, if the first quality indicators are less than the second quality indicators, the first value range is reduced, and if the first quality indicators are greater than the second quality indicators, the first value range is expanded.

For example, one or more first quality indicators may be used, and one or more second quality indicators may also be used. That the first quality indicator is less than the second quality indicator may be that an average value of the first quality indicators is less than an average value of the second quality indicators, and that the first quality indicator is greater than the second quality indicator may be that the average value of the first quality indicators is greater than the average value of the second quality indicators.

For example, for single-target optimization or multiple-target optimization, the smallest quality indicator may be determined from the quality indicators corresponding to the first base values to obtain the first quality indicator. The smallest quality indicator is determined from the quality indicators corresponding to the second base values to obtain the second quality indicator. If the first quality indicator is less than the second quality indicator, the first value range is halved with the first base value corresponding to the first quality indicator as the center or with the second base value corresponding to the second quality indicator as the center. If the first quality indicator is greater than the second quality indicator, the first value range is doubled with the first base value corresponding to the first quality indicator as the center or with the second base value corresponding to the second quality indicator as the center.

In some embodiments, for multiple-target optimization, it may be determined, in the following manner, whether to reduce or expand the first value range. In Operation S213, the reference quality indicator is determined from the quality indicators corresponding to the first base values, and the reference quality indicator may be determined as the first quality indicator. In addition, the second quality indicator is determined from the quality indicators corresponding to the second base values according to the implementation principle in Operation S213. If the first quality indicator is less than the second quality indicator, the first value range is halved with the first base value corresponding to the first quality indicator as the center or with the second base value corresponding to the second quality indicator as the center. If the first quality indicator is greater than the second quality indicator, the first value range is doubled with the first base value corresponding to the first quality indicator as the center or with the second base value corresponding to the second quality indicator as the center.

In the embodiments of this application, the target value is determined in an iterative manner. Therefore, it may be determined, for every specific quantity of iterations, whether to reduce or expand a value range. In other words, in N (N is a positive integer, for example, N is 3) iterations, a previous iteration corresponds to the first quality indicator in the embodiments of this application, and a next iteration corresponds to the second quality indicator in the embodiments of this application. If the first quality indicator is less than the second quality indicator in every two adjacent iterations, the value range is reduced, and if the first quality indicator is greater than the second quality indicator in two adjacent iterations, the value range is expanded.

A length of the reduced value range is not less than a first length, and a length of an expanded value range is not greater than a second length. To be specific, the value ranges before and after reduction and expansion need to be constrained to be appropriate, to avoid extreme cases. In other words, a length of the second value range is not less than the first length, and the length of the second value range is not greater than the second length. The first length is a minimum length of an appropriate value range, the second length is a maximum length of the appropriate value range, and the first length and the second length may be set empirically, or flexibly adjusted according to an application scenario. This is not limited in the embodiments of this application.

In some embodiments, the reducing the value range is also referred to as reducing a mesh, and the expanding the value range is also referred to as expanding the mesh. A value space of the target parameter is optimized by reducing and expanding the mesh. When the second candidate values and the third base values are determined based on the optimized value space subsequently (refer to Operations 2062 to 2065), the accuracy of the second candidate values and the third base values can be improved, and the efficiency of seeking a Pareto optimal solution can be improved, to be specific, the efficiency of determining the target value can be improved. In addition, the value can be kept from being increased blindly, to take both a calculation amount and calculation efficiency into consideration, thereby determining the target value with a small calculation amount and high calculation efficiency.

Operation 2062: Divide the second value range into a plurality of second value intervals.

In the embodiments of this application, an implementation principle of Operation 2062 is similar to the implementation principle of “dividing the first value range into a plurality of first value intervals”, and refer to the description of Operation 201. Details are not described herein again.

Operation 2063: Perform a sampling in the second value intervals to obtain a plurality of first supplementary values and a plurality of second supplementary values.

In the embodiments of this application, a manner of determining the first supplementary values is similar to the manner of determining the first candidate value in Operation 201, and a manner of determining the second supplementary values is similar to the manner of determining the first base values in Operation 201. Therefore, an implementation principle of Operation 2063 is similar to the implementation principle of “performing a sampling in the first value intervals to obtain the plurality of first base values and the plurality of first candidate values”, refer to the description of 201. Details are not described herein again.

Operation 2064: Determine first candidate values other than the first reference values of the plurality of first supplementary values and the plurality of first candidate values as the plurality of second candidate values, and determine a second reference value from a plurality of second candidate values based on the quality indicators corresponding to the second base values.

In the embodiments of this application, the plurality of second candidate values include the first candidate values other than the first reference values of the plurality of first supplementary values and the plurality of first candidate values. The second reference value may be determined from the second candidate values according to the implementation principle similar to that of Operation 203. At least one first reference value and at least one second reference value are used. To be specific, the first candidate values other than the at least one first reference values of the plurality of first supplementary values and the plurality of first candidate values are determined as the plurality of second candidate values, and the at least one second reference value is determined from the plurality of second candidate values based on the quality indicators corresponding to the second base values.

Operation 2065: Determine the plurality of second supplementary values, the plurality of second base values, and the second reference value as the plurality of third base values. To be specific, the plurality of third base values include the second supplementary values, the second base values, and the second reference value.

At least one second reference value is used. To be specific, the plurality of second supplementary values, the plurality of second base values, and the second reference values are determined as the plurality of third base values.

Operation 207: Perform a quality detection on the original layout according to the plurality of third base values by using the layout quality detection tool to obtain quality indicators corresponding to the third base values.

In the embodiments of this application, the layout quality detection tool is determined by making the target parameter include any third base value, an original layout is inputted into the layout quality detection tool, and the layout quality detection tool performs a quality detection on the original layout to obtain a quality indicator of the original layout corresponding to the third base value. At least one quality indicator is used. To be specific, any third base value corresponds to at least one quality indicator, and a result of performing the quality detection on the original layout includes quality indicators corresponding to the third base values. The quality indicator corresponding to the third base value in this embodiment of this application is the quality indicator of the original layout corresponding to the third base value.

An implementation of Operation 207 is similar to the implementation of Operation 202, and refer to the description of Operation 202. Details are not described herein again.

Operation 208: When the quality indicators corresponding to the third base values meet the reference condition, determine the target value of the target parameter based on the third base values.

That a quality indicator corresponding to any third base value meets the reference condition is not limited in the embodiments of this application. For example, it may be determined, based on a quality indicator corresponding to any third base value and a reference threshold, whether the quality indicator corresponding to the third base value meets the reference condition. Alternatively, a quantity of iterations for determining the quality indicators corresponding to the third base values is acquired, and it is determined, based on the quantity of iterations and the quantity threshold, whether the quality indicators corresponding to the third base values meet the reference condition.

Content of that the quality indicator corresponding to the any third base value meets the reference condition is similar to content of that the quality indicator corresponding to the any first base value meets the reference condition, and refer to the description of Operation 203. Details are not described herein again.

If the quality indicators corresponding to the third base values meet the reference condition, the target value may be determined from the plurality of third base values. For a manner of determining the target value from the plurality of third base values, refer to the description of Operation 205, and the implementation principles of the two are similar. Details are not described herein again.

In the embodiments of this application, the determining the target value of the target parameter is equivalent to completing the adjustment of the parameter of the layout quality detection tool, and a layout quality detection tool with a value of the target parameter being the target value is used as a layout quality detection tool with a parameter adjusted, and the accuracy of the layout quality detection tool is high. Subsequently, any chip layout, any mask layout or any wafer layout may be used as the to-be-detected layout. A quality detection is performed on the to-be-detected layout according to the target parameter by using the layout quality detection tool with a parameter adjusted to obtain the quality indicator of the to-be-detected layout.

In some embodiments, a photolithography device in an actual scenario is simulated by using the layout quality detection tool with a parameter adjusted, photolithography is performed on the to-be-detected layout to obtain a photolithography layout, and a pattern analysis is performed on the photolithography layout to obtain the quality indicator of the to-be-detected layout. For example, when the to-be-detected layout is a chip layout, the photolithography layout may be at least one of a mask layout and a wafer layout. When the to-be-detected layout is a mask layout, the photolithography layout may be a wafer layout. When the to-be-detected layout is a chip layout, the photolithography layout is a wafer layout. In this case, the quality indicator of the to-be-detected layout may be determined based on the to-be-detected layout and the photolithography layout by using the layout quality detection tool.

Alternatively, a pattern of the to-be-detected layout may be analyzed according to the target value by using the layout quality detection tool to obtain the quality indicator of the to-be-detected layout.

A manner of determining the quality indicator of the to-be-detected layout is similar to the manner of determining the quality indicator of the original layout, and refer to the description of Operation 202. Details are not described herein again.

Next, it is determined, based on a relationship between the quality indicator of the to-be-detected layout and a target threshold, whether the to-be-detected layout is a base layout. In some embodiments, if the quality indicator is negatively correlated with the quality of the to-be-detected layout, when the quality indicator of the to-be-detected layout is not greater than the target threshold, it is determined that the to-be-detected layout is the base layout, and when the quality indicator of the to-be-detected layout is greater than the target threshold, it is determined that the to-be-detected layout is not the base layout. Similarly, if the quality indicator is positively correlated with the quality of the to-be-detected layout, when the quality indicator of the to-be-detected layout is not less than the target threshold, it is determined that the to-be-detected layout is the base layout, and when the quality indicator of the to-be-detected layout is less than the target threshold, it is determined that the to-be-detected layout is not the base layout.

When the determined to-be-detected layout is a base layout: If the base layout is a chip layout, the photolithography device in the actual scenario may be invoked first, and photolithography is performed on a mask based on the chip layout to obtain the mask after photolithography. Next, the photolithography device in the actual scenario is invoked again to perform photolithography on a wafer based on the mask after photolithography to obtain the wafer after photolithography. If the base layout is a mask layout, the photolithography device in the actual scenario may be invoked, and photolithography is performed on a wafer based on a mask after photolithography corresponding to the mask layout to obtain the wafer after photolithography. Certainly, during application, the base layout may be a layout on the wafer after photolithography, i.e., a wafer layout. In some embodiments, the wafer after photolithography is also referred to as an integrated circuit wafer, and is a product in a chip manufacturing process.

When the base layout is a chip layout or a mask layout, a base layout of high quality is selected, so that integrated circuit wafers of high quality can be manufactured based on the base layout, to reduce a defective rate of integrated circuit wafers, thereby reducing the production costs of integrated circuit wafers. When the base layout is a wafer layout, a base layout of high quality is selected, so that integrated circuit wafers of high quality can be selected, to reduce a defective rate of integrated circuit wafers.

Information (including, but not limited to, device information of a user, and personal information of a user), data (including, but not limited to, data for analysis, stored data, and displayed data), and signals in this application are all authorized by a user or fully authorized by all parties, and the collection, use, and processing of relevant data need to comply with the relevant laws, regulations, and standards of the relevant regions. For example, the original layout, the first value range, and the like in this application are all obtained with full authorization.

In the foregoing method, a target parameter of a layout quality detection tool includes first base values, and a quality detection is performed on an original layout by using the layout quality detection tool to obtain quality indicators corresponding to the first base values. If the quality indicators corresponding to the first base values do not meet a reference condition, a first reference value is determined from a plurality of first candidate values of the target parameter based on the quality indicators corresponding to the first base values, and a plurality of second base values of the target parameter are determined based on the plurality of first base values and the first reference value. The second base values are determined, so that the accuracy of a value space of the target parameter is improved. A quality detection is performed on the original layout by using the layout quality detection tool to obtain quality indicators corresponding to the second base values. The accuracy of the value space of the target parameter is improved, to improve the accuracy of the layout quality detection tool, so that the accuracy of quality indicators is improved, and when the quality indicators corresponding to the second base values meet the reference condition, a target value of the target parameter can be accurately determined based on the second base values, thereby ensuring the accuracy of the layout quality detection tool, helping to improve the accuracy of quality indicators of to-be-detected layouts determined by the layout quality detection tool, and more accurately selecting a layout with better quality from the to-be-detected layouts.

In addition, a sampling is performed in the plurality of first value intervals to obtain the first base values and the first candidate values, which helps to improve the distribution uniformity of the first base values and the first candidate values, thereby ensuring the comprehensiveness of the first base values and the first candidate values. The first base values are determined in a clustering manner, to improve the accuracy of the first base values, so that the efficiency of determining a target value can be increased.

The quality indicators of the original layouts corresponding to the first base values are calculated through errors between the original layout and the predicted layouts corresponding to the first base values, so that the quality indicators of the original layouts corresponding to the first base values can reflect the accuracy of the layout quality detection tool. In this way, a value of the parameter of the layout quality detection tool can be adjusted to be more accurate based on the quality indicators of the original layouts corresponding to the first base values, thereby ensuring the accuracy of the layout quality detection tool.

The reference indicator of the first candidate value is determined by considering the statistical distribution and the statistical information, thereby ensuring the accuracy of the reference indicator of the first candidate value. In addition, in a process of determining the reference indicator of the first candidate value, in consideration of different cases that the first base value corresponds to one or more quality indicators, in the different cases, the reference indicator of the first candidate value is determined in different manners, so that the reliability of the manners of determining the reference indicator of the first candidate value is high, to further ensure the accuracy of the reference indicator of the first candidate value, thereby improving the accuracy of the eventually determined target value.

In a process of determining the first reference value, in consideration of different cases that the first candidate value corresponds to one or more reference indicators, in the different cases, the first reference value is determined in different manners, so that the reliability of the manners of determining the first reference value is high, to further ensure the accuracy of the first reference value, thereby improving the accuracy of the eventually determined target value.

A value space of the target parameter is optimized by reducing and expanding the value range of the target parameter. When the second candidate values and the third base values are determined based on the optimized value space, the accuracy of the second candidate values and the third base values can be improved, and the efficiency of determining the target value can be improved. In addition, the value can be kept from being increased blindly, to take both a calculation amount and calculation efficiency into consideration, thereby determining the target value with a small calculation amount and high calculation efficiency.

The method provided in the embodiments of this application is described above from the perspective of method operations, and is described below with reference to a scenario. Two scenarios are provided in the embodiments of this application. One is a scenario of determining a parameter of a layout quality detection tool for a single quality indicator, and the other is a scenario of determining a parameter of a layout quality detection tool for two quality indicators. The two scenarios are separately described below.

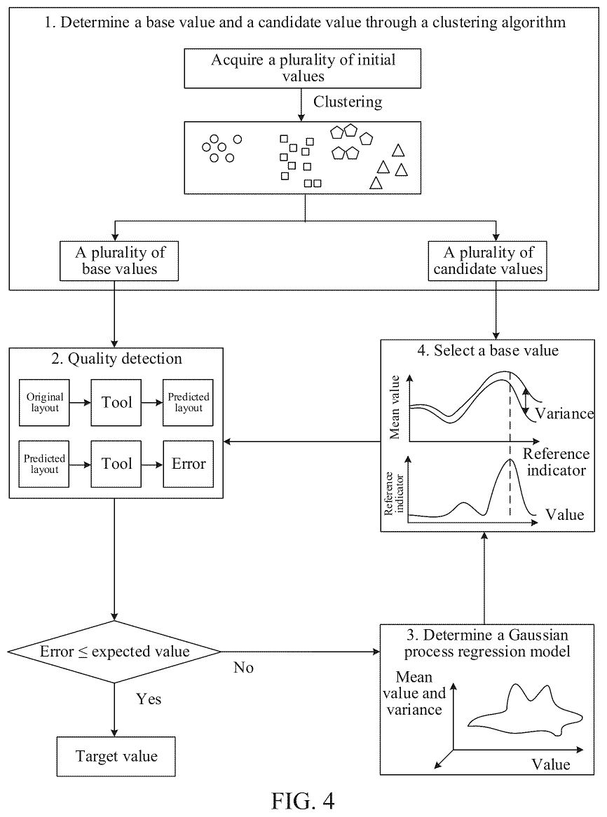

First, the scenario of determining a parameter of a layout quality detection tool for a single quality indicator is described. For example, the quality indicator is an error. FIG. 4 is a schematic flowchart of determining a parameter of a layout quality detection tool for a single quality indicator according to an embodiment of this application. The procedure includes Operation 1 to Operation 4 below.

Operation 1: Determine a base value and a candidate value through a clustering algorithm.

In the embodiments of this application, a plurality of initial values may be acquired, and the plurality of initial values are clustered to obtain clusters. For any cluster, an initial value having the smallest distance from a cluster center of the cluster is selected from the cluster, the selected initial value is used as the base value, and an unselected initial value is used as the candidate value. In this manner, the plurality of initial values are classified into base values and a plurality of candidate values. For an implementation of Operation 1, refer to the description of Operation 201. Details are not described herein again.

Operation 2: Perform a quality detection on an original layout by using a layout quality detection tool by making a target parameter of the layout quality detection tool include a plurality of base values to obtain errors of original layouts corresponding to the base values.

In the embodiments of this application, the layout quality detection tool is determined by making the target parameter of the layout quality detection tool any base value. The original layout is inputted into the layout quality detection tool, and a predicted layout corresponding to the base value is outputted through the layout quality detection tool. Next, the predicted layout corresponding to the base value is inputted into the layout quality detection tool, and the layout quality detection tool determines an error of the original layout corresponding to the base value. In this manner, the errors corresponding to the base values may be determined. For an implementation of Operation 2, refer to the description of Operation 202. Details are not described herein again.

If the errors corresponding to the base values are less than or equal to an expected value, a target value is determined based on the base values. For a manner of determining the target value, refer to the description of Operation 205. Details are not described herein again. If the errors corresponding to the base values are greater than the expected value, Operation 3 is performed.

Operation 3: Determine a Gaussian process regression model based on the errors corresponding to the base values.

In the embodiments of this application, the errors corresponding to the base values meet a Gaussian distribution. In this case, the Gaussian process regression model is configured for describing a mapping relationship between a base value and a mean value of a Gaussian distribution and a variance of the Gaussian distribution. For an implementation principle of Operation 3, refer to the description of Operation S1. Details are not described herein again.

Operation 4: Determine, based on the Gaussian process regression model and a plurality of candidate values, reference indicators of the candidate values, and select the base value from the plurality of candidate values based on the reference indicators of the candidate values.

In the embodiments of this application, the Gaussian process regression model is configured for describing a mapping relationship between a base value and a mean value of a Gaussian distribution and a variance of the Gaussian distribution. Therefore, any candidate value is mapped into a corresponding mean value and variance by using the Gaussian process regression model. Next, based on a mean value and a variance corresponding to any candidate value, a reference indicator of the candidate value is determined, and it is determined, based on the reference indicator of the candidate value, whether the candidate value is a base value. In this manner, the base value is selected from the plurality of candidate values. For an implementation principle of Operation 4, refer to the description of Operation S2, Implementation A1, and Implementation B1. Details are not described herein again.

Next, the base value selected in Operation 4 and the base value determined in Operation 1 are considered as base values in one set, and Operation 2 is performed again based on these base values to obtain the errors corresponding to the base values. If the errors corresponding to the base values are less than or equal to the expected value, the target value is determined based on the base values. If the errors corresponding to the base values are greater than the expected value, Operation 3, Operation 4, and Operation 2 are performed repeatedly, until the target value is determined.

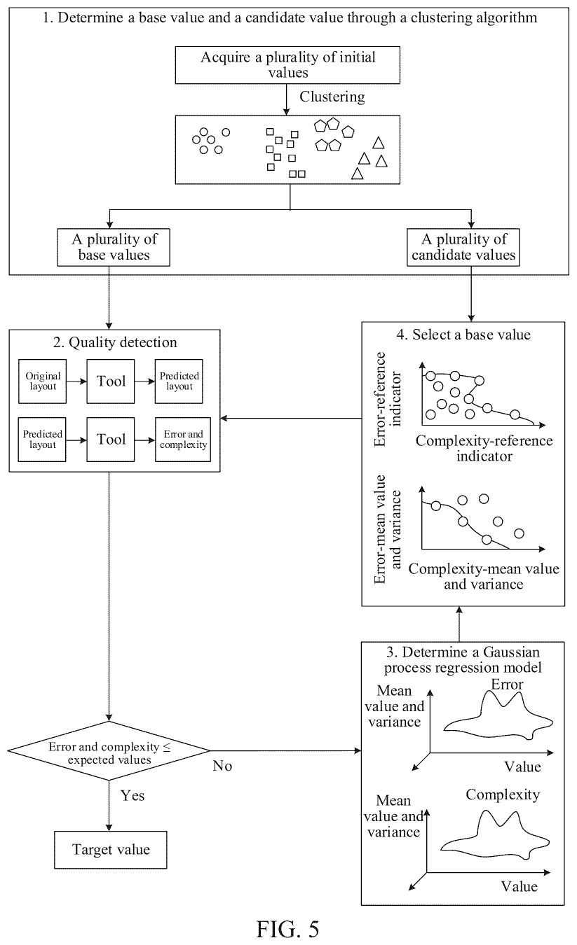

Next, the scenario of determining a parameter of a layout quality detection tool for a plurality of quality indicators is described. For example, the plurality of quality indicators are two quality indicators, and the two quality indicators are an error and a complexity. FIG. 5 is a schematic flowchart of determining a parameter of a layout quality detection tool for two quality indicators according to an embodiment of this application. The procedure includes Operation 1 to Operation 4 below.

Operation 1: Determine a base value and a candidate value through a clustering algorithm.

In the embodiments of this application, a plurality of initial values may be acquired, and the plurality of initial values are clustered to obtain clusters. For any cluster, an initial value having the smallest distance from a cluster center of the cluster is selected from the cluster, the selected initial value is used as the base value, and an unselected initial value is used as the candidate value. In this manner, the plurality of initial values are classified into base values and a plurality of candidate values. For an implementation of Operation 1, refer to the description of Operation 201. Details are not described herein again.

Operation 2: Perform a quality detection on an original layout by using a layout quality detection tool by making a target parameter of the layout quality detection tool include a plurality of base values to obtain errors and complexities of original layouts corresponding to the base values.

In the embodiments of this application, the layout quality detection tool is determined by making the target parameter of the layout quality detection tool any base value. The original layout is inputted into the layout quality detection tool, and a predicted layout corresponding to the base value is outputted through the layout quality detection tool. Next, the predicted layout corresponding to the base value is inputted into the layout quality detection tool. In one aspect, the layout quality detection tool determines an error of the original layout corresponding to the base value. In another aspect, the layout quality detection tool determines a complexity of the original layout corresponding to the base value. In this manner, the errors and complexities corresponding to the base values may be determined. For an implementation of Operation 2, refer to the description of Operation 202. Details are not described herein again.

If the errors corresponding to the base values are less than or equal to an expected value corresponding to the errors and the complexities corresponding to the base values are less than or equal to an expected value corresponding to the complexities, a target value is determined based on the base values. For a manner of determining the target value, refer to the description of Operation 205. Details are not described herein again. If an error corresponding to a base value is greater than an expected value corresponding to the error, and/or a complexity corresponding to a base value is greater than an expected value corresponding to the complexity, Operation 3 is performed.

Operation 3: Determine, based on the errors corresponding to the base values, a Gaussian process regression model corresponding to the errors, and determine, based on the complexities corresponding to the base values, a Gaussian process regression model corresponding to the complexities.

In the embodiments of this application, the errors corresponding to the base values meet a Gaussian distribution. In this case, the Gaussian process regression model corresponding to the errors is configured for describing a mapping relationship between a base value and a mean value of a Gaussian distribution that the errors meet and a variance of the Gaussian distribution. Similarly, the complexities corresponding to the base values also meet the Gaussian distribution. In this case, the Gaussian process regression model corresponding to the complexities is configured for describing a mapping relationship between a base value and a mean value of a Gaussian distribution that the complexities meet and a variance of the Gaussian distribution. For an implementation principle of Operation 3, refer to the description of Operation S1. Details are not described herein again.

Operation 4: Determine, based on the Gaussian process regression model and a plurality of candidate values, reference indicators of the candidate values, and select the base value from the plurality of candidate values based on the reference indicators of the candidate values.

In the embodiments of this application, the Gaussian process regression model corresponding to the errors is configured for describing a mapping relationship between a base value and a mean value of a Gaussian distribution that the errors meet and a variance of the Gaussian distribution. Therefore, any candidate value is mapped into a mean value and a variance that correspond to an error by using the Gaussian process regression model corresponding to the error. Based on the similar principle, any candidate value is mapped into a mean value and a variance that correspond to a complexity by using the Gaussian process regression model corresponding to the complexity.

Next, based on a mean value and a variance that correspond to an error of any candidate value and a mean value and a variance that correspond to a complexity of the candidate value, a reference indicator corresponding to the error of the candidate value and a reference indicator corresponding to the complexity of the candidate value are determined, to determine, based on the reference indicator corresponding to the error of the candidate value and the reference indicator corresponding to the complexity of the candidate value, whether the candidate value is a base value. In this manner, the base value is selected from the plurality of candidate values. For an implementation principle of Operation 4, refer to the description of Operation S2, Implementation A2, and Implementation B2. Details are not described herein again.

Next, the base value selected in Operation 4 and the base value determined in Operation 1 are considered as base values in one set, and Operation 2 is performed again based on these base values to obtain the errors and the complexities corresponding to the base values. If the errors corresponding to the base values are less than or equal to an expected value corresponding to the errors and the complexities corresponding to the base values are less than or equal to an expected value corresponding to the complexities, a target value is determined based on the base values; or otherwise, Operation 3, Operation 4, and Operation 2 are performed repeatedly, until the target value is determined.

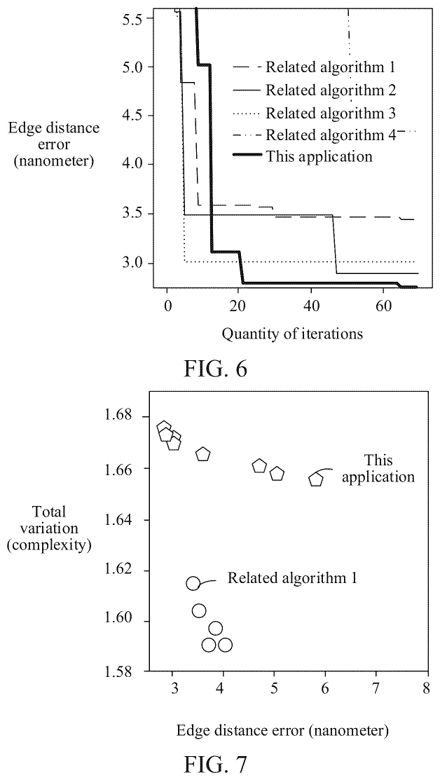

In the embodiments of this application, according to the flowchart in FIG. 4, a parameter of the layout quality detection tool is determined for an edge distance error. Statistics of a relationship between a quantity of iterations and an edge distance error is collected to obtain a corresponding relationship line in FIG. 6. In addition, the parameter of the layout quality detection tool is further determined for the edge distance error by using four correlation algorithms. Statistics of relationships between a quantity of iterations and an edge distance error corresponding to various correlation algorithms is collected to obtain relationship lines corresponding to Correlation algorithms 1 to 4 in FIG. 6. Correlation algorithm 1 is a random algorithm, Correlation algorithm 2 is a particle swarm optimization (PSO) algorithm, Correlation algorithm 3 is a social learning particle swarm optimization (SLPSO) algorithm, and Correlation algorithm 4 is a random walking (RW) algorithm.

As can be learned from FIG. 6, after 20 iterations, the relationship line corresponding to this application has the smallest edge distance error, and converges faster compared with the correlation algorithms. As can be learned, the method in the embodiments of this application can determine a value of a target parameter of high accuracy with a small calculation amount, thereby improving the accuracy of the layout quality detection tool.

In addition, according to the flowchart in FIG. 5, a parameter of the layout quality detection tool may be determined for an edge distance error and a complexity. A data distribution corresponding to this application in FIG. 7 is obtained by collecting statistics of a relationship between an edge distance error and a related complexity total variation. In addition, the parameter of the layout quality detection tool is further determined for the edge distance error and the complexity by using Correlation algorithm 1. A data distribution corresponding to Correlation algorithm 1 in FIG. 7 is obtained by collecting statistics of a relationship between an edge distance error and a related complexity total variation.

As can be learned from FIG. 7, in multiple-target optimization, compared with the correlation algorithms, the method in the embodiments of this application can reach a smaller edge distance error. Each piece of data in FIG. 7 is a Pareto optimal solution. The data distribution of this application corresponds to 8 Pareto optimal solutions, and the data distribution of Correlation algorithm 1 corresponds to 5 Pareto optimal solutions, indicating that the method in the embodiments of this application has more Pareto optimal solutions, making the accuracy of the layout quality detection tool higher.

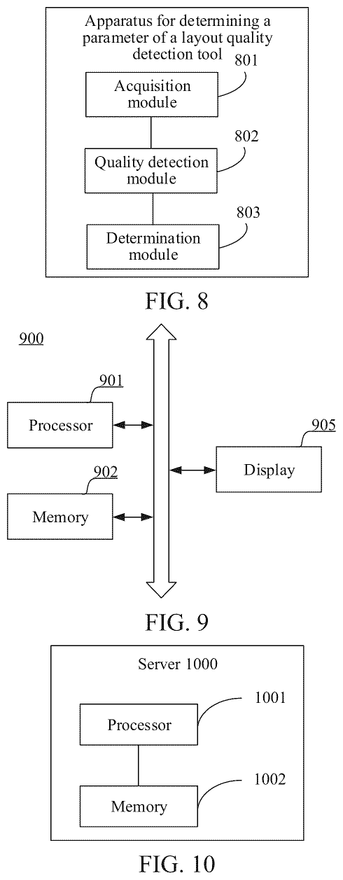

FIG. 8 is a schematic structural diagram of an apparatus for determining a parameter of a layout quality detection tool according to an embodiment of this application. As shown in FIG. 8, the apparatus includes:
an acquisition module 801, configured to acquire a plurality of first base values of a target parameter of a layout quality detection tool and a plurality of first candidate values of the target parameter;
a quality detection module 802, configured to perform a quality detection on an original layout according to the plurality of first base values by using the layout quality detection tool to obtain quality indicators corresponding to the first base values; and
a determination module 803, configured to: when the quality indicators corresponding to the first base values do not meet a reference condition, determine a first reference value from the plurality of first candidate values based on the quality indicators corresponding to the first base values, and determine a plurality of second base values of the target parameter based on the plurality of first base values and the first reference value;
the quality detection module 802 being further configured to perform a quality detection on the original layout according to the plurality of second base values by using the layout quality detection tool to obtain quality indicators corresponding to the second base values;
the determination module 803 being further configured to: when the quality indicators corresponding to the second base values meet the reference condition, determine a target value of the target parameter based on the second base values, and use a layout quality detection tool with a value of the target parameter being the target value as a layout quality detection tool with a parameter adjusted, the layout quality detection tool with a parameter adjusted being configured to determine a quality indicator of a to-be-detected layout.

In a possible implementation, the acquisition module 801 is configured to: acquire a first value range of the target parameter; divide the first value range into a plurality of first value intervals; and perform a sampling in the first value intervals to obtain the plurality of first base values and the plurality of first candidate values.

In a possible implementation, the acquisition module 801 is configured to: perform the sampling in the first value intervals to obtain a plurality of first initial values of the target parameter; cluster the plurality of first initial values to obtain a plurality of target clusters, any target cluster including at least one first initial value of the plurality of first initial values; and for any target cluster in the plurality of target clusters, select the first base values from the first initial values included in the any target cluster, and determine the first initial values other than the first base values in the any target cluster as the first candidate values.

In a possible implementation, the quality detection module 802 is configured to: process the original layout according to the plurality of first base values by using the layout quality detection tool to obtain predicted layouts corresponding to the first base values, and determine the quality indicators corresponding to the first base values based on the predicted layouts corresponding to the first base values.

In a possible implementation, the quality detection module 802 is configured to: for any first base value of the first base values, determine an error between the original layout and a predicted layout corresponding to the any first base value; and determine a quality indicator corresponding to the any first base value based on the error between the original layout and the predicted layout corresponding to the any first base value.

In a possible implementation, the determination module 803 is configured to: determine reference indicators of the first candidate values based on the quality indicators corresponding to the first base values, a reference indicator of any first candidate value being configured for describing a case that a quality indicator meets the reference condition when a quality detection is performed on the original layout by using the layout quality detection tool when the target parameter includes the any first candidate value; and determine the first reference value from the plurality of first candidate values based on the reference indicators of the first candidate values.

In a possible implementation, the determination module 803 is configured to: determine a first mapping relationship based on the first base values and the quality indicators corresponding to the first base values, the first mapping relationship being configured for describing a mapping relationship between the first base values and statistical information of a statistical distribution when the quality indicators corresponding to the first base values meets the statistical distribution; and for any first candidate value of the first candidate values, determine statistical information corresponding to the any first candidate value based on the any first candidate value and the first mapping relationship, and determine the reference indicator of the any first candidate value based on the statistical information corresponding to the any first candidate value.

In a possible implementation, the statistical information corresponding to the any first candidate value includes a mean value and a variance; and the determination module 803 is configured to: determine a reference quality indicator from the quality indicators corresponding to the first base values; determine a normal distribution function of the any first candidate value based on the reference quality indicator and the mean value and the variance that correspond to the any first candidate value; and determine the reference indicator of the any first candidate value based on the variance corresponding to the any first candidate value, the normal distribution function corresponding to the any first candidate value, and a cumulative density function and a probability density function of the normal distribution function corresponding to the any first candidate value.

In a possible implementation, any first base value corresponds to one quality indicator; and the determination module 803 is configured to: determine the smallest quality indicator from the quality indicators corresponding to the first base values, and determine the smallest quality indicator as the reference quality indicator.

In a possible implementation, any first base value corresponds to a plurality of quality indicators; and the determination module 803 is configured to: for any quality indicator of the plurality of quality indicators, determine a maximum value and a minimum value of the any quality indicator from the any quality indicators corresponding to the first base values; for the any quality indicator corresponding to the any first base value, determine a priority indicator of the any quality indicator corresponding to the any first base value based on a first selected quality indicator, a weight of the first selected quality indicator, and the maximum value and the minimum value of the first selected quality indicator, the first selected quality indicator being at least one quality indicator of the plurality of quality indicators corresponding to the any first base value, the first selected quality indicator including the any quality indicator corresponding to the any first base value; and determine the reference quality indicator from the quality indicators corresponding to the first base values based on priority indicators of the quality indicators corresponding to the first base values.

In a possible implementation, the determination module 803 is configured to: determine a difference between the reference quality indicator and the mean value corresponding to the any first candidate value; and use a quotient of the difference by the variance corresponding to the any first candidate value as the normal distribution function of the any first candidate value.

In a possible implementation, the determination module 803 is configured to: multiply the normal distribution function corresponding to the any first candidate value by the cumulative density function of the normal distribution function corresponding to the any first candidate value to obtain a multiplication result; add the multiplication result to the probability density function of the normal distribution function corresponding to the any first candidate value to obtain an addition result; and multiply the addition result by the variance corresponding to the any first candidate value to obtain the reference indicator of the any first candidate value.

In a possible implementation, any first candidate value corresponds to one reference indicator, and the determination module 803 is configured to select a first candidate value with a reference indicator not less than a set indicator threshold from the plurality of first candidate values based on the reference indicators of the first candidate values as the first reference value.

In a possible implementation, any first candidate value corresponds to a plurality of reference indicators; and the determination module 803 is configured to: for any reference indicator of the plurality of reference indicators, determine a maximum value and a minimum value of the any reference indicator from the any reference indicators corresponding to the first candidate values; for any reference indicator corresponding to the any first candidate value, determine a priority indicator of the any reference indicator corresponding to the any first candidate value based on a selected reference indicator and a maximum value and a minimum value of the selected reference indicator, the selected reference indicator being at least one reference indicator of the plurality of reference indicators corresponding to the any first candidate value, the selected reference indicator including the any reference indicator corresponding to the any first candidate value; determine a target indicator from reference indicators corresponding to the first candidate values based on priority indicators of the reference indicators corresponding to the first candidate values; and determine a first candidate value corresponding to the target indicator as the first reference value.

In a possible implementation, the determination module 803 is further configured to: when the quality indicators corresponding to the second base values do not meet the reference condition, determine a second reference value from a plurality of second candidate values based on the quality indicators corresponding to the second base values, and determine a plurality of third base values based on the plurality of second base values and the second reference value, the plurality of second candidate values including first candidate values other than the first reference values of the plurality of first candidate values;
the quality detection module 802 is further configured to perform a quality detection on the original layout according to the plurality of third base values by using the layout quality detection tool to obtain quality indicators corresponding to the third base values; and
the determination module 803 is further configured to: when the quality indicators corresponding to the third base values meet the reference condition, determine the target value of the target parameter based on the third base values.

In a possible implementation, the determination module 803 is configured to: adjust the first value range of the target parameter to obtain a second value range of the target parameter; divide the second value range into a plurality of second value intervals; perform a sampling in the second value intervals to obtain a plurality of first supplementary values and a plurality of second supplementary values; determine first candidate values other than the first reference values of the plurality of first supplementary values and the plurality of first candidate values as the plurality of second candidate values; determine the second reference value from the plurality of second candidate values based on the quality indicators corresponding to the second base values; and determine the plurality of second supplementary values, the plurality of second base values, and the second reference value as the plurality of third base values.

In a possible implementation, the determination module 803 is configured to: determine a first quality indicator with a quality indicator not greater than a first indicator threshold from the quality indicators corresponding to the first base values; determine a second quality indicator with a quality indicator not greater than a second indicator threshold from the quality indicators corresponding to the second base values; when the first quality indicator is less than the second quality indicator, reduce the first value range to obtain the second value range; and when the first quality indicator is greater than the second quality indicator, expand the first value range to obtain the second value range.

In a possible implementation, a length of the second value range is not less than a first length, and the length of the second value range is not greater than a second length.

In a possible implementation, the determination module 803 is configured to: for any first base value of the plurality of first base values, adjust the any first base value based on the first reference value to obtain an adjusted base value corresponding to the any first base value; and use adjusted base values corresponding to the first base values as the plurality of second base values.

In a possible implementation, any second base value corresponds to one quality indicator, and the determination module 803 is configured to: select a second base value with a quality indicator greater than or less than a set threshold from the plurality of second base values, and use the selected second base value as the target value.

In a possible implementation, any second base value corresponds to a plurality of quality indicators, and the determination module 803 is configured to: for any quality indicator of the plurality of quality indicators, determine a maximum value and a minimum value of the any quality indicator from the any quality indicators corresponding to the second base values; for the any quality indicator corresponding to the any second base value, determine a priority indicator of the any quality indicator corresponding to the any second base value based on a second selected quality indicator and a maximum value and a minimum value of the second selected quality indicator, the second selected quality indicator being at least one quality indicator of the plurality of quality indicators corresponding to the any second base value, the second selected quality indicator including the any quality indicator corresponding to the any second base value; determine a target quality indicator from the quality indicators corresponding to the second base values based on priority indicators of the quality indicators corresponding to the second base values; and determine a second base value corresponding to the target quality indicator as the target value.

In the foregoing apparatus, a target parameter of a layout quality detection tool includes first base values, and a quality detection is performed on an original layout by using the layout quality detection tool to obtain quality indicators corresponding to the first base values. If the quality indicators corresponding to the first base values do not meet a reference condition, a first reference value is determined from a plurality of first candidate values of the target parameter based on the quality indicators corresponding to the first base values, and a plurality of second base values of the target parameter are determined based on the plurality of first base values and the first reference value. The second base values are determined, so that the accuracy of a value space of the target parameter is improved. A quality detection is performed on the original layout by using the layout quality detection tool to obtain quality indicators corresponding to the second base values. The accuracy of the value space of the target parameter is improved, to improve the accuracy of the layout quality detection tool, so that the accuracy of quality indicators is improved, and when the quality indicators corresponding to the second base values meet the reference condition, a target value of the target parameter can be accurately determined based on the second base values, thereby ensuring the accuracy of the layout quality detection tool, helping to improve the accuracy of quality indicators of to-be-detected layouts determined by the layout quality detection tool, and more accurately selecting a layout with better quality from the to-be-detected layouts.

When the foregoing apparatus provided in FIG. 8 implements functions thereof, the division of the foregoing functional modules is merely used as an example for description. In practice, the foregoing functions may be assigned to and completed by different functional modules as required. That is, an internal structural division of the device may be divided into different functional modules to complete all or some of the functions described above. In addition, the information storage apparatus provided in the foregoing embodiment belongs to the same conception as the embodiment of the information storage method. For a specific implementation process thereof, refer to the method embodiment. Details are not described herein again.

FIG. 9 is a schematic block diagram of a terminal device 900 according to an exemplary embodiment of this application. The terminal device 900 includes a processor 901 and a memory 902.

The processor 901 may include one or more processing cores such as a 4-core processor or an 8-core processor. The processor 901 may be implemented by using at least one hardware form of a digital signal processor (DSP), a field programmable gate array (FPGA), and a programmable logic array (PLA). The processor 901 may alternatively include a main processor and a coprocessor. The main processor is configured to process data in an active state, also referred to as a central processing unit (CPU). The coprocessor is a low-power processor configured to process data in a standby state. In some embodiments, the processor 901 may be integrated with a graphics processing unit (GPU). The GPU is configured to render and draw content that needs to be displayed on a display. In some embodiments, the processor 901 may further include an artificial intelligence (AI) processor. The AI processor is configured to process a computing operation related to machine learning.

The memory 902 may include one or more computer-readable storage media. The computer-readable storage media may be non-transient. The memory 902 may further include a high-speed random access memory and a non-volatile memory, such as one or more magnetic disk storage devices or a flash storage device. In some embodiments, the non-transient computer-readable storage medium in the memory 902 is configured to store at least one computer program, and the at least one computer program is configured to be executed by the processor 901 to cause the terminal device 900 to implement the method for determining a parameter of a layout quality detection tool provided in the method embodiments of this application.

In some embodiments, the terminal device 900 may include a display screen 905.

The display screen 905 is configured to display a UI. The UI may include a graph, a text, an icon, a video, and any combination thereof. When the display screen 905 is a touch display screen, the display screen 905 is further capable of collecting a touch signal on or above a surface of the display screen 905. The touch signal may be used as a control signal to be inputted to the processor 901 for processing. In this case, the display screen 905 may further be configured to provide a virtual button and/or a virtual keyboard that are/is also referred to as a soft button and/or a soft keyboard. In some embodiments, there may be one display screen 905, disposed on a front panel of the terminal device 900. In some other embodiments, there may be at least two display screens 905, respectively disposed on different surfaces of the terminal device 900 or designed in a foldable shape. In some other embodiments, the display screen 905 may be a flexible display screen, disposed on a curved surface or a folded surface of the terminal device 900. Even, the display screen 905 may be further set to have a non-rectangular irregular pattern, that is, a special-shaped screen. The display screen 905 may be made of materials such as a liquid crystal display (LCD) and an organic light-emitting diode (OLED). For example, the original layout, the predicted layout, the to-be-detected layout, and the like may be displayed through the display screen 905.

A person skilled in the art may understand that the structure shown in FIG. 9 does not constitute a limitation to the terminal device 900, and the terminal may include more components or fewer components than those shown in the figure, or some components may be combined, or a different component deployment may be used

FIG. 10 is a schematic structural diagram of a server according to an embodiment of this application. The server 1000 may vary greatly due to different configurations or performance, and may include one or more processors 1001 and one or more memories 1002. The one or more memories 1002 stores at least one computer program, the at least one computer program being loaded and executed by the one or more processors 1001 to implement the method for determining a parameter of a layout quality detection tool provided in the foregoing method embodiments. For example, the processor 1001 is a CPU. Certainly, the server 1000 may also have a wired or wireless network interface, a keyboard, an input/output interface and other components to facilitate input/output. The server 1000 may also include other components for implementing device functions. Details are not described herein again.

In exemplary embodiments, a non-transitory computer-readable storage medium is further provided, the non-transitory computer-readable storage medium having at least one computer program stored therein, the at least one computer program being loaded and executed by a processor, to cause an electronic device to implement any foregoing method for determining a parameter of a layout quality detection tool.

In some embodiments, the foregoing non-transitory computer-readable storage medium may be a read-only memory (ROM), a random access memory (RAM), a compact disc ROM (CD-ROM), a magnetic tape, a floppy disk, an optical data storage device, or the like.

In exemplary embodiments, a computer program is further provided, at least one computer program product being provided, the at least one computer program being loaded and executed by a processor, to cause an electronic device to implement any foregoing method for determining a parameter of a layout quality detection tool.

In exemplary embodiments, a computer program product is further provided, the computer program product having at least one computer program stored therein, the at least one computer program being loaded and executed by a processor, to cause an electronic device to implement any foregoing method for determining a parameter of a layout quality detection tool.

“Plurality of” mentioned in this specification means two or more. “And/or” describes an association relationship for describing associated objects and represents that three relationships may exist. For example, A and/or B may represent the following three cases: only A exists, both A and B exist, and only B exists. The character “/” generally indicates an “or” relationship between the associated objects.

The foregoing descriptions are merely examples of the embodiments of this application, but are not intended to limit this application. Any modification, equivalent replacement, or improvement made without departing from the spirit and principle of this application shall fall within the protection scope of this application.

What is claimed is:

1. A method for determining a parameter of a layout quality detection tool performed by an electronic device, the method comprising:
performing a quality detection on an original chip layout by using a layout quality detection tool according to a plurality of first base values of a target parameter of the layout quality detection tool to obtain quality indicators corresponding to the first base values;
when the quality indicators corresponding to the first base values do not meet a reference condition, determining a first reference value from a plurality of first candidate values of the target parameter of the layout quality detection tool based on the quality indicators corresponding to the first base values, and determining a plurality of second base values of the target parameter based on the plurality of first base values and the first reference value;
performing a quality detection on the original layout by using the layout quality detection tool according to the plurality of second base values to obtain quality indicators corresponding to the second base values; and
when the quality indicators corresponding to the second base values meet the reference condition, determining a target value of the target parameter based on the second base values for adjusting the layout quality detection tool to determine a quality indicator of a to-be-detected chip layout.

2. The method according to claim 1, wherein the plurality of first base values and the plurality of first candidate values of the target parameter is obtained by:
acquiring a first value range of the target parameter;
dividing the first value range into a plurality of first value intervals; and
performing a sampling in the first value intervals to obtain the plurality of first base values and the plurality of first candidate values.

3. The method according to claim 1, wherein the performing a quality detection on an original chip layout by using a layout quality detection tool according to a plurality of first base values of a target parameter of the layout quality detection tool to obtain quality indicators corresponding to the first base values comprises:
processing the original chip layout according to the plurality of first base values by using the layout quality detection tool to obtain predicted chip layouts corresponding to the first base values; and
determining the quality indicators corresponding to the first base values based on the predicted chip layouts corresponding to the first base values.

4. The method according to claim 1, wherein the determining a first reference value from the plurality of first candidate values based on the quality indicators corresponding to the first base values comprises:
determining reference indicators of the first candidate values based on the quality indicators corresponding to the first base values, a reference indicator of a first candidate value being configured for describing a case that a quality indicator meets the reference condition when a quality detection is performed on the original layout by using the layout quality detection tool when the target parameter comprises the first candidate value; and determining the first reference value from the plurality of first candidate values based on the reference indicators of the first candidate values.

5. The method according to claim 1, wherein the method further comprises:
when the quality indicators corresponding to the second base values do not meet the reference condition, determining a second reference value from a plurality of second candidate values based on the quality indicators corresponding to the second base values, and determining a plurality of third base values based on the plurality of second base values and the second reference value, the plurality of second candidate values comprising first candidate values other than the first reference values of the plurality of first candidate values;
performing a quality detection on the original layout according to the plurality of third base values by using the layout quality detection tool to obtain quality indicators corresponding to the third base values; and
when the quality indicators corresponding to the third base values meet the reference condition, determining the target value of the target parameter based on the third base values.

6. The method according to claim 1, wherein the determining a plurality of second base values of the target parameter based on the plurality of first base values and the first reference value comprises:
for any first base value of the plurality of first base values, adjusting the any first base value based on the first reference value to obtain an adjusted base value corresponding to the any first base value; and
using adjusted base values corresponding to the first base values as the plurality of second base values.

7. The method according to claim 1, wherein any second base value corresponds to one quality indicator, and the determining a target value of the target parameter based on the second base values comprises:
selecting a second base value with a quality indicator greater than or less than a set threshold from the plurality of second base values, and using the selected second base value as the target value.

8. The method according to claim 1, wherein any second base value corresponds to a plurality of quality indicators, and the determining a target value of the target parameter based on the second base values comprises:
for any quality indicator of the plurality of quality indicators, determining a maximum value and a minimum value of the any quality indicator from the any quality indicators corresponding to the second base values;
for the any quality indicator corresponding to the any second base value, determining a priority indicator of the any quality indicator corresponding to the any second base value based on a second selected quality indicator and a maximum value and a minimum value of the second selected quality indicator, the second selected quality indicator being at least one quality indicator of the plurality of quality indicators corresponding to the any second base value, the second selected quality indicator comprising the any quality indicator corresponding to the any second base value; and
determining a target quality indicator from the quality indicators corresponding to the second base values based on priority indicators of the quality indicators corresponding to the second base values; and determining a second base value corresponding to the target quality indicator as the target value.

9. An electronic device comprising a processor and a memory, the memory having at least one computer program stored therein that, when loaded and executed by the processor, causes the electronic device to implement a method for determining a parameter of a layout quality detection tool including:
performing a quality detection on an original chip layout by using a layout quality detection tool according to a plurality of first base values of a target parameter of the layout quality detection tool to obtain quality indicators corresponding to the first base values;
when the quality indicators corresponding to the first base values do not meet a reference condition, determining a first reference value from a plurality of first candidate values of the target parameter of the layout quality detection tool based on the quality indicators corresponding to the first base values, and determining a plurality of second base values of the target parameter based on the plurality of first base values and the first reference value;
performing a quality detection on the original layout by using the layout quality detection tool according to the plurality of second base values to obtain quality indicators corresponding to the second base values; and
when the quality indicators corresponding to the second base values meet the reference condition, determining a target value of the target parameter based on the second base values for adjusting the layout quality detection tool to determine a quality indicator of a to-be-detected chip layout.

10. The electronic device according to claim 9, wherein the plurality of first base values and the plurality of first candidate values of the target parameter is obtained by:
acquiring a first value range of the target parameter;
dividing the first value range into a plurality of first value intervals; and
performing a sampling in the first value intervals to obtain the plurality of first base values and the plurality of first candidate values.

11. The electronic device according to claim 9, wherein the performing a quality detection on an original chip layout by using a layout quality detection tool according to a plurality of first base values of a target parameter of the layout quality detection tool to obtain quality indicators corresponding to the first base values comprises:
processing the original chip layout according to the plurality of first base values by using the layout quality detection tool to obtain predicted chip layouts corresponding to the first base values; and
determining the quality indicators corresponding to the first base values based on the predicted chip layouts corresponding to the first base values.

12. The electronic device according to claim 9, wherein the determining a first reference value from the plurality of first candidate values based on the quality indicators corresponding to the first base values comprises:
determining reference indicators of the first candidate values based on the quality indicators corresponding to the first base values, a reference indicator of a first candidate value being configured for describing a case that a quality indicator meets the reference condition when a quality detection is performed on the original layout by using the layout quality detection tool when the target parameter comprises the first candidate value; and determining the first reference value from the plurality of first candidate values based on the reference indicators of the first candidate values.

13. The electronic device according to claim 9, wherein the method further comprises:
when the quality indicators corresponding to the second base values do not meet the reference condition, determining a second reference value from a plurality of second candidate values based on the quality indicators corresponding to the second base values, and determining a plurality of third base values based on the plurality of second base values and the second reference value, the plurality of second candidate values comprising first candidate values other than the first reference values of the plurality of first candidate values;
performing a quality detection on the original layout according to the plurality of third base values by using the layout quality detection tool to obtain quality indicators corresponding to the third base values; and
when the quality indicators corresponding to the third base values meet the reference condition, determining the target value of the target parameter based on the third base values.

14. The electronic device according to claim 9, wherein the determining a plurality of second base values of the target parameter based on the plurality of first base values and the first reference value comprises:
for any first base value of the plurality of first base values, adjusting the any first base value based on the first reference value to obtain an adjusted base value corresponding to the any first base value; and
using adjusted base values corresponding to the first base values as the plurality of second base values.

15. The electronic device according to claim 9, wherein any second base value corresponds to one quality indicator, and the determining a target value of the target parameter based on the second base values comprises:
selecting a second base value with a quality indicator greater than or less than a set threshold from the plurality of second base values, and using the selected second base value as the target value.

16. The electronic device according to claim 9, wherein any second base value corresponds to a plurality of quality indicators, and the determining a target value of the target parameter based on the second base values comprises:
for any quality indicator of the plurality of quality indicators, determining a maximum value and a minimum value of the any quality indicator from the any quality indicators corresponding to the second base values;
for the any quality indicator corresponding to the any second base value, determining a priority indicator of the any quality indicator corresponding to the any second base value based on a second selected quality indicator and a maximum value and a minimum value of the second selected quality indicator, the second selected quality indicator being at least one quality indicator of the plurality of quality indicators corresponding to the any second base value, the second selected quality indicator comprising the any quality indicator corresponding to the any second base value; and
determining a target quality indicator from the quality indicators corresponding to the second base values based on priority indicators of the quality indicators corresponding to the second base values; and determining a second base value corresponding to the target quality indicator as the target value.

17. A non-transitory computer-readable storage medium having at least one computer program stored therein that, when loaded and executed by a processor of an electronic device, causes the electronic device to implement a method for determining a parameter of a layout quality detection tool including:
performing a quality detection on an original chip layout by using a layout quality detection tool according to a plurality of first base values of a target parameter of the layout quality detection tool to obtain quality indicators corresponding to the first base values;
when the quality indicators corresponding to the first base values do not meet a reference condition, determining a first reference value from a plurality of first candidate values of the target parameter of the layout quality detection tool based on the quality indicators corresponding to the first base values, and determining a plurality of second base values of the target parameter based on the plurality of first base values and the first reference value;
performing a quality detection on the original layout by using the layout quality detection tool according to the plurality of second base values to obtain quality indicators corresponding to the second base values; and
when the quality indicators corresponding to the second base values meet the reference condition, determining a target value of the target parameter based on the second base values for adjusting the layout quality detection tool to determine a quality indicator of a to-be-detected chip layout.

18. The non-transitory computer-readable storage medium according to claim 17, wherein the plurality of first base values and the plurality of first candidate values of the target parameter is obtained by:
acquiring a first value range of the target parameter;
dividing the first value range into a plurality of first value intervals; and
performing a sampling in the first value intervals to obtain the plurality of first base values and the plurality of first candidate values.

19. The non-transitory computer-readable storage medium according to claim 17, wherein the performing a quality detection on an original chip layout by using a layout quality detection tool according to a plurality of first base values of a target parameter of the layout quality detection tool to obtain quality indicators corresponding to the first base values comprises:
processing the original chip layout according to the plurality of first base values by using the layout quality detection tool to obtain predicted chip layouts corresponding to the first base values; and
determining the quality indicators corresponding to the first base values based on the predicted chip layouts corresponding to the first base values.

20. The non-transitory computer-readable storage medium according to claim 17, wherein the determining a plurality of second base values of the target parameter based on the plurality of first base values and the first reference value comprises:
for any first base value of the plurality of first base values, adjusting the any first base value based on the first reference value to obtain an adjusted base value corresponding to the any first base value; and
using adjusted base values corresponding to the first base values as the plurality of second base values.
